(19) United States
(12) Patent Application Publication
(10) Pub. No.: US 2003/0015754 A1
(43) Pub. Date: Jan. 23, 2003

(54) Nonvolatile semiconductor memory device

(75) Inventors: Atsushi Fukumoto, Hyogo (JP); Satoshi Shimizu, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/118,139

(22) Filed: Apr. 9, 2002

(30) Foreign Application Priority Data
Jul. 17, 2001 (JP) 2001-216581(P)

(51) Int. Cl. H01L 29/788

(52) U.S. Cl. 257/315

(57) ABSTRACT

A nonvolatile semiconductor memory device of a high reliability is provided. The nonvolatile semiconductor memory device includes a capacitor. Capacitor includes a lower electrode, a second dielectric layer and an upper electrode which has a portion formed above lower electrode by allowing second dielectric layer to intervene. Upper electrode has a first top surface positioned in a portion relatively far away from silicon substrate and a second top surface positioned in a portion relatively close to silicon substrate. Second dielectric layer has a structure wherein a first silicon oxide film, a silicon nitride film and a second silicon oxide film are sequentially layered.

### BACKGROUND OF THE INVENTION

1. Field of the Invention

The present invention relates to a nonvolatile semiconductor memory device, in particular, to a nonvolatile semiconductor memory device which has a capacitor.

2. Description of the Background Art

A nonvolatile semiconductor device which has a capacitor is conventionally known as a nonvolatile semiconductor device. FIG. 61 is a cross section view showing a conventional nonvolatile semiconductor memory device disclosed in U.S. Pat. No. 6,015,984. Referring to FIG. 61, the conventional nonvolatile semiconductor memory device is provided with a substrate 601, a tunnel oxide film 603 formed on substrate 601, a floating gate 606 formed on tunnel oxide film 603, an ONO (oxide nitride oxide) layer 620 formed on floating gate 606 and a control gate 613 formed on ONO layer 620.

A field oxide film 602 is formed on substrate 601. Tunnel oxide film 603 is formed on field oxide film 602. A bottom electrode 607 is formed on tunnel oxide film 603. ONO layer 620 is formed on bottom electrode 607. A top electrode 615 is formed on ONO layer 620.

A nonvolatile memory cell transistor has tunnel oxide film 603, floating gate 606, ONO layer 620 and control gate 613. A capacitor is formed of bottom electrode 607, ONO layer 620 and top electrode 615. Floating gate 606 and bottom electrode 607 are formed of the same conductive layer. Control gate 613 and top electrode 615 are formed of the same conductive layer.

FIG. 62 is a cross section view of the nonvolatile semiconductor memory device shown for the purpose of describing a problem point. Referring to FIG. 62, an interlayer insulating film 630 is formed on substrate 601. A resist pattern 631 is formed on interlayer insulating film 630 and contact holes 630a and 630b are created in interlayer insulating film 630 through etching by using resist pattern 631 as a mask. At this time, the depths of contact hole 630a and of contact hole 630b differ greatly. Therefore, when interlayer insulating film 630 is etched for a long period of time in order to create contact hole 630a, top electrode 615 and ONO layer 620, which originally should not be etched, are also etched so that contact hole 630b reaches to bottom electrode 607. Thereby, a problem arises that the capacitor does not function so that the reliability the nonvolatile semiconductor device is lowered.

### SUMMARY OF THE INVENTION

Therefore, the present invention is provided in order to solve the above described problem point and the purpose of the invention is to provide a nonvolatile semiconductor memory device which has a high reliability.

A nonvolatile semiconductor memory device according to this invention is provided with a semiconductor substrate, a nonvolatile memory cell transistor formed on the semiconductor substrate and a capacitor formed on the semiconductor substrate. The nonvolatile memory cell transistor includes a floating gate electrode formed on the semiconductor substrate with a gate insulating film interposed therebetween, a first dielectric layer formed on the floating gate electrode and a control gate electrode formed on the first dielectric layer. The capacitor includes a lower electrode formed on the semiconductor substrate, a second dielectric layer formed on the lower electrode and an upper electrode having a portion formed on the lower electrode with the second dielectric layer interposed therebetween. The floating gate electrode and the lower electrode include conductive layers arranged in the same layer. The first dielectric layer and the second dielectric layer include dielectric layers arranged in the same layer. The control gate electrode and the upper electrode include conductive layers arranged in the same layer. The upper electrode has a first top surface located relatively far apart from the semiconductor substrate and a second top surface, which is located relatively close to the semiconductor substrate and which is formed on the semiconductor substrate so as to continue to the first top surface.

In the nonvolatile semiconductor memory device formed in the above manner, the upper electrode has the first top surface located in a portion which is relatively far away from the semiconductor substrate and the second top surface which is formed on the semiconductor substrate so as to continue to the first top surface and which has a portion relatively close to the semiconductor substrate. Thereby, the second top surface is located in a portion relatively close to the semiconductor substrate and, therefore, when an interlayer insulating film is formed on the semiconductor substrate and a hole which reaches to the semiconductor substrate and a hole which reaches to the second top surface are created in this interlayer insulating film, the difference of the depths of these holes becomes small. Therefore, the possibility becomes small where the hole which reaches to the second top surface goes through the upper electrode and the second dielectric layer so that the reliability of the nonvolatile semiconductor memory device is improved.

In addition, the floating gate electrode and the lower electrode include the same conductive layer, the first dielectric layer and the second dielectric layer include the same dielectric layer and the control gate electrode and the upper electrode include the same conductive layer and, therefore, they can be manufactured by means of the same process. Therefore, the nonvolatile semiconductor memory device can be manufactured in a smaller number of manufacturing steps.

In addition, the first dielectric layer and the second dielectric layer, preferably, have a structure wherein a first silicon oxide film, a silicon nitride film and a second silicon oxide film are sequentially layered. In this case, the first dielectric layer and the second dielectric layer both have a silicon nitride film so that the first dielectric layer and the second dielectric layer can increase the dielectric constant in comparison with the case where they are formed only of a silicon oxide film.

In addition, the nonvolatile semiconductor memory device is, preferably, further provided with an interlayer insulating film formed on the semiconductor substrate. The first hole which reaches to the semiconductor substrate and the second hole which reaches to the second top surface of the upper electrode are formed in the interlayer insulating film. In this case, since the second top surface of the upper electrode is positioned in a portion relatively close to the semiconductor substrate, the depth of the first hole and the depth of the second hole become relatively small. As a result, the possibility becomes small where the second hole goes through the upper electrode as well as the second dielectric layer formed beneath the electrode at the time when the second hole is created so that the reliability of the nonvolatile semiconductor memory device is improved.

In addition, the semiconductor substrate preferably has a main surface so that the main surface and the first top surface and the second top surface are almost parallel.

In addition, the nonvolatile semiconductor memory device is preferably further provided with a separation insulating film formed on the semiconductor substrate. The lower electrode and the upper electrode are formed on the separation insulating film. In this case, since the lower electrode and the upper electrode are formed on the separation insulating film, the semiconductor substrate and the capacitor can be electrically separated.

In addition, the nonvolatile semiconductor memory device is preferably further provided with a diode connected to the lower electrode. In this case, since the capacitor and the diode are connected, a booster circuit can be formed by using the capacitor and the diode so that a high voltage which is applied to the nonvolatile memory cell transistor can be generated.

In addition, the diode and the lower electrode are preferably formed in the same layer so as to directly contact each other. In this case, since the diode and the lower electrode are formed in the same layer, the manufacturing steps for the diode and the lower electrode can be reduced in comparison with the case where they are formed in different layers.

In addition, the nonvolatile semiconductor memory device is preferably further provided with an interlayer insulating film formed on the semiconductor substrate. A first hole which reaches to the semiconductor substrate, a second hole which reaches to a portion of the second top surface of the upper electrode and a third hole which reaches to the diode are formed in the interlayer insulating film. In this case, the difference between the depths of the first hole which reaches to the semiconductor substrate, of the second hole which reaches to the second top surface located in a portion relatively close to the semiconductor substrate and of the third hole which reaches to the diode located in a portion closer to the semiconductor substrate than the upper electrode becomes smaller. Therefore, the possibility of excessive etching of the capacitor becomes less when these holes are created. Therefore, the reliability of the nonvolatile semiconductor memory device is further improved.

In addition, the lower electrode preferably has a top surface and a side surface. The upper electrode faces a portion of the top surface and a portion of the sides of the lower electrode with the second dielectric layer interposed therebetween. In this case, the area where the upper electrode faces the lower electrode can be increased by the portion where the upper electrode faces the sides of the lower electrode in comparison with the case where the upper electrode faces only the top surface of the lower electrode so that the capacitance of the capacitor can be increased.

In addition, the upper electrode preferably faces the entirety of the sides with the second dielectric layer interposed therebetween. In this case, the area where the upper electrode and the lower electrode face each other can be further increased so that the capacitance of the capacitor is further increased.

In addition, the nonvolatile semiconductor memory device is preferably further provided with a external periphery layer formed on the semiconductor substrate so as to surround the upper electrode and the lower electrode. The height of the top surface of the external periphery layer and the height of the first top surface of the upper electrode are almost equal. In this case, since the external periphery layer is formed so as to surround the upper electrode and the lower electrode, a difference in level vis-à-vis the periphery part becomes smaller when the upper electrode and the lower electrode are processed so that the upper electrode and the lower electrode can be processed without fail.

Furthermore, since the height of the top surface of the external periphery layer and the height of the first top surface of the upper electrode become almost equal, a difference in level vis-à-vis the periphery part can be reduced when the upper electrode and the lower electrode are formed so that the upper electrode and the lower electrode can be processed without fail.

In addition, the external periphery layer is preferably formed in the same layer as the layer forming the lower electrode, the second dielectric layer and the upper electrode. In this case, since the external periphery layer can be manufactured by the same process as the process for formed the lower electrode, the second dielectric layer and the upper electrode, the external periphery layer can be formed without increasing the manufacturing steps.

In addition, the nonvolatile semiconductor memory device is preferably further provided with a memory cell region in which a nonvolatile memory cell transistor is formed and with a periphery region in which a capacitor is formed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a nonvolatile semiconductor memory device according to a first embodiment of the present invention;

FIG. 2 is a plan view showing a memory cell region of the nonvolatile semiconductor memory device according to the first embodiment of the present invention;

FIG. 3 is a plan view showing a periphery region of the nonvolatile semiconductor memory device according to the first embodiment of the present invention;

FIG. 4 is a plan view showing a periphery circuit region of the nonvolatile semiconductor memory device according to the first embodiment of the present invention;

FIG. 5 is a view showing a cross section along line V-V in FIG. 2;

FIG. 6 is a cross section view showing the enlargement of the portion surrounded by VI in FIG. 5;

FIG. 7 is a view showing a cross section along line VII-VII in FIG. 2;

FIG. 8 is a view showing a cross section along line VIII-VIII in FIG. 3;

FIG. 9 is a cross section view showing the enlargement of the portion surrounded by IX in FIG. 8;

FIG. 10 is a view showing a cross section along line X-X in FIG. 4;

FIGS. 11, 15, 19, 23, 27, 31, 35, 39, 43 and 47 are cross section views showing the first to the tenth steps of a process for the memory cell region shown in FIG. 5;

FIGS. 12, 16, 20, 24, 28, 32, 36, 40, 44 and 48 are cross section views showing the first to the tenth steps of a process for the memory cell region shown in FIG. 7;

FIGS. 13, 17, 21, 25, 29, 33, 37, 41, 45 and 49 are cross section views showing the first to the tenth steps of a process for the periphery region shown in FIG. 8;

FIGS. 14, 18, 22, 26, 30, 34, 38, 42, 46 and 50 are cross section views showing the first to the tenth steps of a process for the periphery circuit region shown in FIG. 10;

FIG. 51 is a plan view showing a periphery region of a nonvolatile semiconductor memory device according to a second embodiment of the present invention;

FIG. 52 is a view showing a cross section along line LII-LII in FIG. 51;

FIG. 53 is a cross section view showing the first step of a process for a periphery region shown in FIG. 52;

FIG. 54 is a cross section view showing the second step of the process for a periphery region shown in FIG. 52;

FIG. 55 is a plan view of a periphery region of a nonvolatile semiconductor memory device according to a third embodiment of the present invention;

FIG. 56 is a plan view of a periphery region of a nonvolatile semiconductor memory device according to a fourth embodiment of the present invention;

FIG. 57 is a plan view of a periphery region of a nonvolatile semiconductor memory device according to a fifth embodiment of the present invention;

FIG. 58 is a view showing a cross section along line LVIII-LVIII in FIG. 57;

FIG. 59 is a cross section view showing a process for the periphery region shown in FIGS. 57 and 58;

FIG. 60 is a plan view of a periphery region of a nonvolatile semiconductor memory device according to a sixth embodiment of the present invention;

FIG. 61 is a cross section view of a nonvolatile semiconductor memory device according to a prior art; and

FIG. 62 is a cross section view of the nonvolatile semiconductor memory device shown for the purpose of describing a problem point.

### DESCRIPTION OF THE PREFERRED EMBODIMENTS

(First Embodiment)

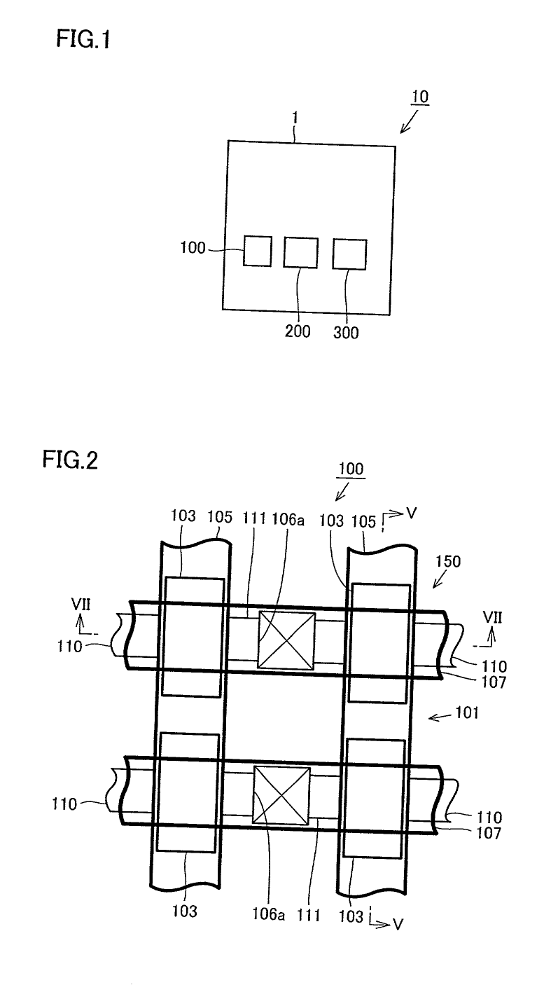

Referring to FIG. 1, a nonvolatile semiconductor memory device 10 according to a first embodiment of this invention has a silicon substrate 1 as a semiconductor substrate, a memory cell region 100 formed on silicon substrate 1, a periphery region 200 formed on silicon substrate 1 and a periphery circuit region 300 formed on silicon substrate 1.

Memory cell region 100 is a region for storing information and desired data is stored in a memory cell region 100. Transistors, capacitors, diodes, and the like, are provided in periphery region 200 and periphery circuit region 300, which are regions for controlling the operation of memory cell region 100. Here, the arrangement of memory cell region 100, periphery region 200 and periphery circuit region 300 is not limited to the one shown in FIG. 1 and, for example, memory cell region 100 may occupy a larger area than the area shown in FIG. 1. In addition, it is possible to appropriately change the arrangement of these three regions.

Referring to FIG. 2, a particular of nonvolatile memory cell transistors 150 are formed in memory cell region 100. A nonvolatile memory cell transistor 150 is an EEPROM (electrically erasable programmable read only memory) wherein writing and erasing are electrically possible and, for example, is a flash memory. A plurality of source regions 110 and drain regions 111 of nonvolatile memory cell transistors 150 are formed on the silicon substrate. A source region 110 and a drain region 111 form an active region and are formed so as to extend in one direction.

Source region 110 and drain region 111 are separated from each other by a field oxide film 101 as a separation insulating film.

A floating gate electrode 103 is formed between source region 110 and drain region 111. Floating gate electrode 103 is formed in an island form so as to extend in the direction approximately perpendicular to the direction in which source region 110 and drain region 111 extend.

A control gate electrode 105 is formed in a band form on floating gate electrode 103. Here, though in FIG. 2, the width of the control gate electrode 105 appears wider than the width of floating gate electrode 103, in reality, the width of control gate electrode 105 and the width of floating gate electrode 103 are almost equal.

Control gate electrode 105 extends in the direction approximately perpendicular to the direction in which source region 110 and drain region 111 extend and is formed so as to extend approximately parallel to the direction in which floating gate electrode 103, in an island form, extends. Here, control gate electrode 105 forms a so-called word line.

A wiring layer 107 is formed above control gate electrode 105. Wiring layer 107 extends in the direction approximately perpendicular to the direction in which control gate electrode 105 extends. Wiring layer 107 is electrically connected to drain region 111 through a contact hole 106a. That is to say, the potential of drain region 111 and the potential of wiring layer 107 are equal.

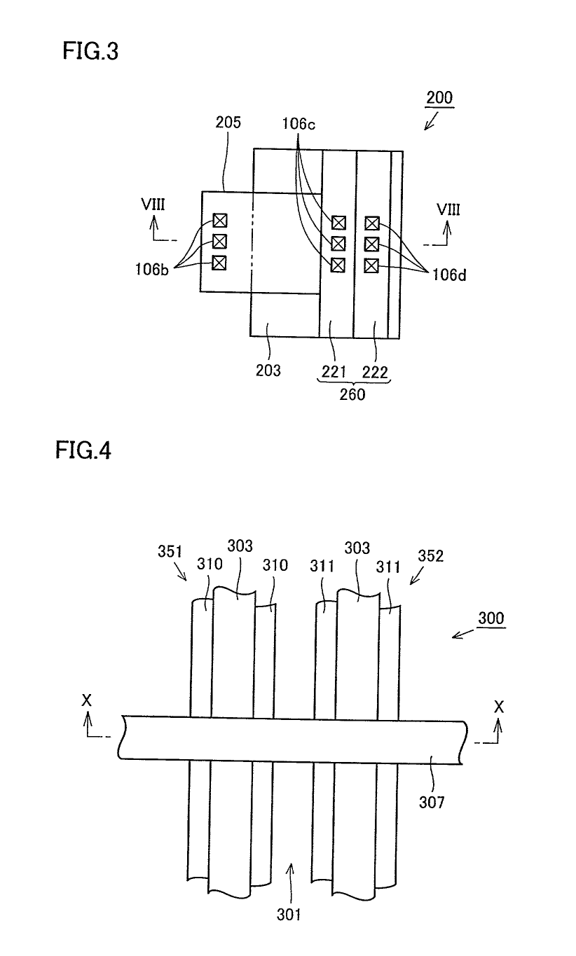

Referring to FIG. 3, periphery region 200 has capacitors 250. A capacitor 250 has a lower electrode 203 formed on the silicon substrate and an upper electrode 205 which is formed above lower electrode 203 by allowing a second dielectric layer (not shown in FIG. 3) to intervene. Lower electrode 203 is connected to a diode 260 where diode 260 and lower electrode 203 are formed in the same layer. Diode 260 has a structure wherein an n-type region 221, into which n-type impurities are doped, and a p-type region 222, into which p-type impurities are doped, are connected in series. A contact hole 106c is connected to n-type region 221 while a contact hole 106d is connected to p-type region 222. Upper electrode 205 is formed so as to cover a portion of lower electrode 203 and to not cover diode 260.

Referring to FIG. 4, field effect transistors 351 and 352 are formed in periphery circuit region 300. Field effect transistor 351 is formed of a gate electrode 303 and of n-type impurity regions 310 formed on both sides of gate electrode 303. Field effect transistor 351 is a so-called n-type transistor. Field effect transistor 352 has gate electrode 303 and p-type impurity regions 311 provided on both sides of gate electrode 303. Field effect transistor 352 is a so-called p-type transistor. A wiring layer 307 is formed above field effect transistors 351 and 352. Wiring layer 307 extends in the direction almost perpendicular to the direction in which gate electrode 303 extends.

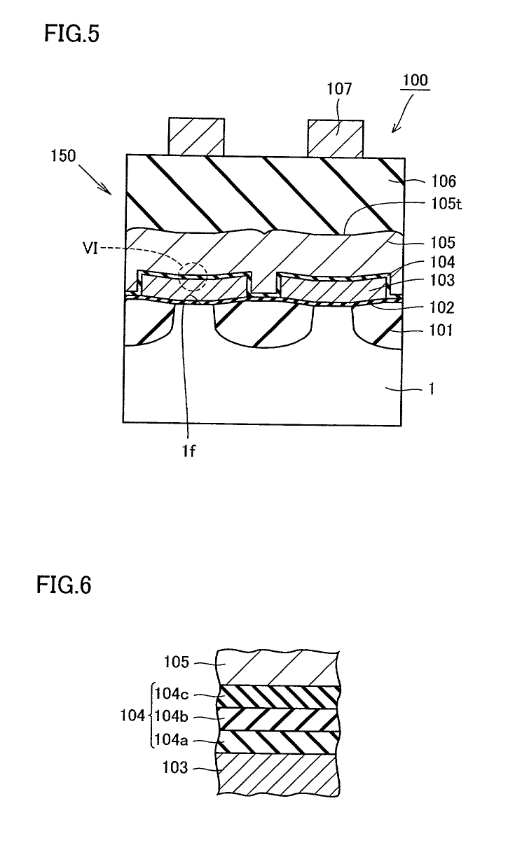

Referring to FIG. 5, nonvolatile memory cell transistor 150 formed on silicon substrate 1 includes floating gate electrode 103 formed above silicon substrate 1 as a semiconductor substrate by allowing tunnel oxide film 102 to intervene as a gate insulating film, a first dielectric layer 104 formed on floating gate electrode 103 and control gate electrode 105 formed on the first dielectric layer 104.

A plurality of field oxide films 101 are formed on a main surface 1f of silicon substrate 1. Tunnel oxide film 102 is formed on main surface 1f of silicon substrate 1 and on field oxide film 101. Floating gate electrode 103, in an island form, is formed on tunnel oxide film 102. Floating gate electrode 103 is formed of a polysilicon which becomes conductive by being doped with impurities. First dielectric layer 104 is formed so as to cover floating gate electrode 103 and tunnel oxide film 102.

Referring to FIG. 6, first dielectric layer 104 has a first silicon oxide film 104a, a silicon nitride film 104b and a second silicon oxide film 104c. Control gate electrode 105 is formed on first dielectric layer 104. Control gate electrode 105 contacts second silicon oxide film 104c.

Again referring to FIG. 5, an interlayer insulating film 106 made of a silicon oxide film is formed on control gate electrode 105. Slight amounts of impurities such as boron or phosphorous may be added to interlayer insulating film 106. Wiring layer 107 is formed on interlayer insulating film 106. Wiring layer 107 is formed of an aluminum alloy which includes copper. Control gate electrode 105 extends on the paper from left to right while wiring layer 107 extends in the direction perpendicular to control gate electrode 105, that is to say, from the front side to the rear side of the paper.

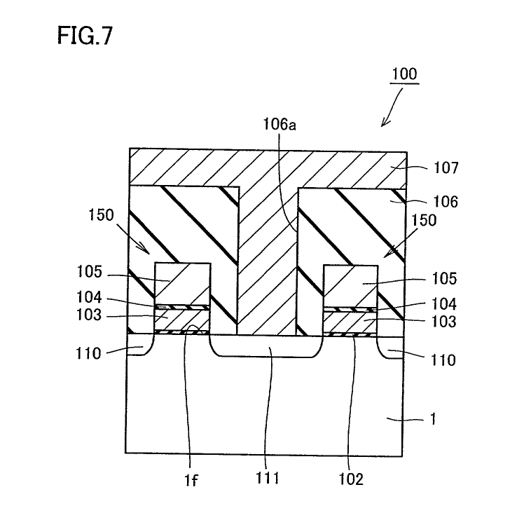

Referring to FIG. 7, a plurality of nonvolatile memory cell transistors 150 are formed in memory cell region 100. Source region 110 and drain region 111, which are one component of a nonvolatile memory cell transistor 150, are formed in silicon substrate 1. Source region 110 and drain region 111 are formed by injecting impurities in main surface 1f of silicon substrate 1. Tunnel oxide film 102 is formed on main surface 1f of silicon substrate 1 and in the region between source region 110 and drain region 111. Floating gate electrode 103, first dielectric layer 104 and control gate electrode 105, which have rectangular cross sections, are formed on tunnel oxide film 102. In the cross section shown in FIG. 7 the width of floating gate electrode 103 and the width of control gate electrode 105 are equal.

Interlayer insulating film 106 is formed on main surface 1f of silicon substrate 1 so as to cover floating gate electrode 103, first dielectric layer 104 and control gate electrode 105. Contact hole 106a is created in interlayer insulating film 106 so as to reach to drain region 111. Wiring layer 107 is formed so as to fill in contact hole 106a and to contact drain region 111.

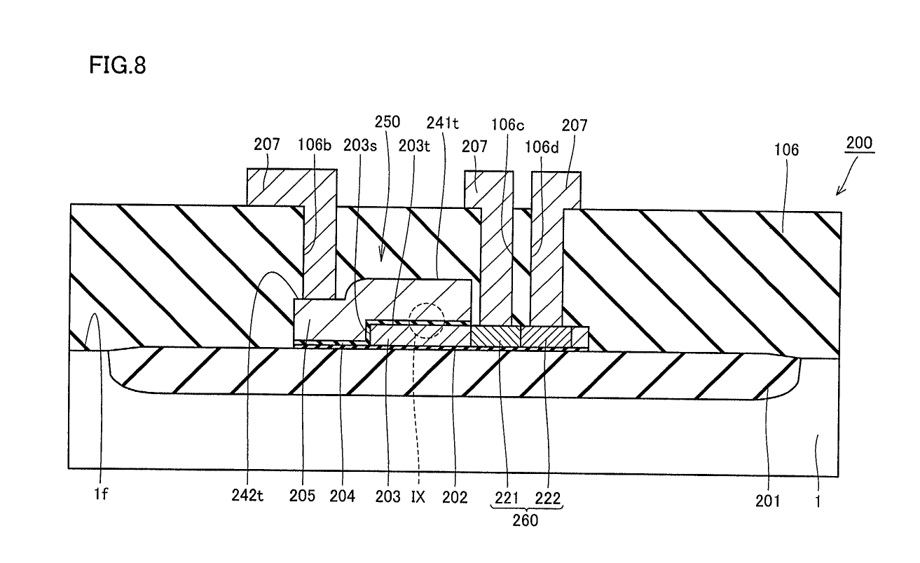

Referring to FIG. 8, field oxide film 201 is formed on the surface of silicon substrate 1 as a separation insulating film. A capacitor 250 is formed on field oxide film 201. Capacitor 250 is formed of a lower electrode 203 formed above field oxide film 201 by allowing tunnel oxide film 202 to intervene, second dielectric layer 204 formed on lower electrode 203 and upper electrode 205 formed on second dielectric layer 204.

Lower electrode 203 has a top surface 203t and a side surface 203s. Top surface 203t is positioned approximately parallel to main surface 1f while side surface 203s is positioned approximately perpendicular to main surface 1f. Second dielectric layer 204 is formed of first silicon oxide film 104a formed on lower electrode 203, silicon nitride film 104b formed on first silicon oxide film 104a and second silicon oxide film 104c formed on silicon nitride film 104b. Second dielectric layer 204 is a so-called ONO film.

Upper electrode 205 is provided on second dielectric layer 204. Upper electrode 205 has first top surface 241t positioned in a portion relatively far away from silicon substrate 1 and second top surface 242t positioned in a portion relatively close to silicon substrate 1.

Diode 260 is formed in the same layer as the layer forming lower electrode 203. Diode 260 is formed of n-type region 221 into which n-type impurities are injected and p-type region 222 into which p-type impurities are injected. N-type region 221 and p-type region 222 directly contact each other and, thereby, a pn junction is formed. Interlayer insulating film 106 is formed so as to cover capacitor 250 and diode 260. Contact holes 106b, 106c and 106d are created in interlayer insulating film 106 and contact hole 106b reaches to second top surface 242t of upper electrode 205. Contact hole 106c reaches to n-type region 221 of diode 260. Contact hole 106d reaches to n-type region 222 of diode 260. Wiring layer 207 is formed so as to fill in contact holes 106b, 106c and 106d and to contact upper electrode 205, n-type region 221 and p-type region 222.

Referring to FIG. 10, a plurality of field effect transistors 351 and 352 are formed in periphery circuit region 300. Field effect transistors 351 and 352 are separated by field oxide film 301 formed on silicon substrate 1. N-type impurity region 310 and p-type impurity region 311 are formed in main surface 1f of silicon substrate 1. Gate electrode 303 is formed between one pair of n-type impurity regions 310 by allowing gate oxide film 302 to intervene on main surface 1f of silicon substrate 1. Gate electrode 303 is formed between one pair of p-type impurity regions 311 by allowing gate oxide film 302 to intervene on main surface 1f of silicon substrate 1. Interlayer insulating film 106 is formed on main surface 1f of silicon substrate 1 so as to cover gate electrode 303. Wiring layer 307 is formed on interlayer insulating film 106 so as to extend in the direction approximately perpendicular to the direction in which gate electrode 303 extends.

Referring to FIGS. 5 to 8, the nonvolatile semiconductor memory device is provided with silicon substrate 1 as a semiconductor substrate, a nonvolatile memory cell transistor 150 formed on silicon substrate 1 and capacitor 250 formed on silicon substrate 1.

Nonvolatile memory cell transistor 150 includes floating gate electrode 103 formed on silicon substrate 1 by allowing tunnel oxide film 102 to intervene as a gate insulating film, first dielectric layer 104 formed on floating gate electrode 103 and control gate electrode 105 formed on first dielectric layer 104.

Capacitor 250 includes lower electrode 203 formed on silicon substrate 1, second dielectric layer 204 formed on lower electrode 203 and upper electrode 205, which has a portion formed above lower electrode 203 by allowing second dielectric layer 204 to intervene.

Floating gate electrode 103 and lower electrode 203 include a conductive layer arranged in the same layer. First dielectric layer 104 and second dielectric layer 204 include a dielectric layer arranged in the same layer. Control gate electrode 105 and upper electrode 205 include a conductive layer arranged in the same layer. Upper electrode 205 has first top surface 241t positioned in a portion relatively far away from silicon substrate 1 and second top surface 242t which is formed on silicon substrate 1 so as to continue to first top surface 241t and which is positioned in a portion relatively close to silicon substrate 1.

First dielectric layer 104 and second dielectric layer 204 have a structure wherein first silicon oxide film 104a, silicon nitride film 104b and second silicon oxide film 104c are sequentially layered. The nonvolatile semiconductor memory device further includes interlayer insulating film 106 formed on silicon substrate 1. Contact hole 106a, as a first hole that reaches to silicon substrate 1, and contact hole 106b, as a second hole that reaches to second top surface 204t of upper electrode 205, are formed in interlayer insulating film 106.

Silicon substrate 1 has main surface 1f, and main surface 1f, first top surface 241t and second top surface 242t are approximately parallel to each other.

The nonvolatile semiconductor memory device is further provided with field oxide film 201 as a separation insulating film formed on silicon substrate 1. Lower electrode 203 and upper electrode 205 are formed above field oxide film 201. Here, lower electrode 203 and upper electrode 205 may be formed above main surface 1f.

The nonvolatile semiconductor memory device further includes diode 260 connected to lower electrode 203. Diode 260 and lower electrode 203 are formed of the same layer so as to directly contact each other.

The nonvolatile semiconductor memory device is further provided with interlayer insulating film 106 formed on silicon substrate 1. Contact hole 106a, as a first hole that reaches to silicon substrate 1, contact hole 106b, as a second hole that reaches to second top surface 242t of upper electrode 205, and contact holes 106c and 106d, as third holes that reach to diode 260, are formed in interlayer insulating film 106.

Lower electrode 203 has top surface 203t and side surface 203s. Upper electrode 205 faces a portion of top surface 203t of lower electrode 203 and a portion of side surface 203s by allowing second dielectric layer 204 to intervene.

The nonvolatile semiconductor memory device further includes memory cell region 100 in which nonvolatile memory cell transistor 150 is formed and periphery region 200 in which capacitor 250 is formed.

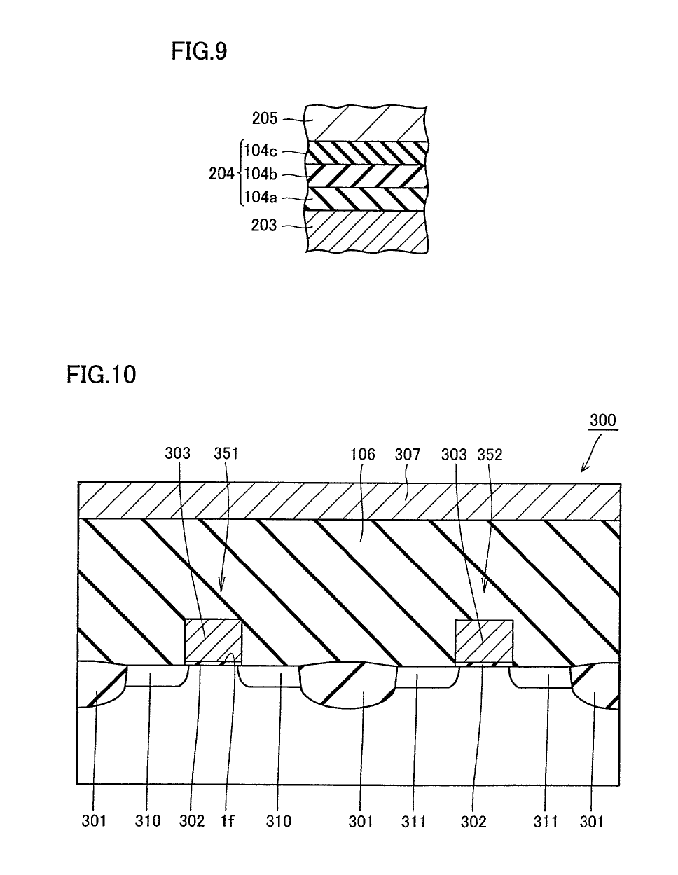

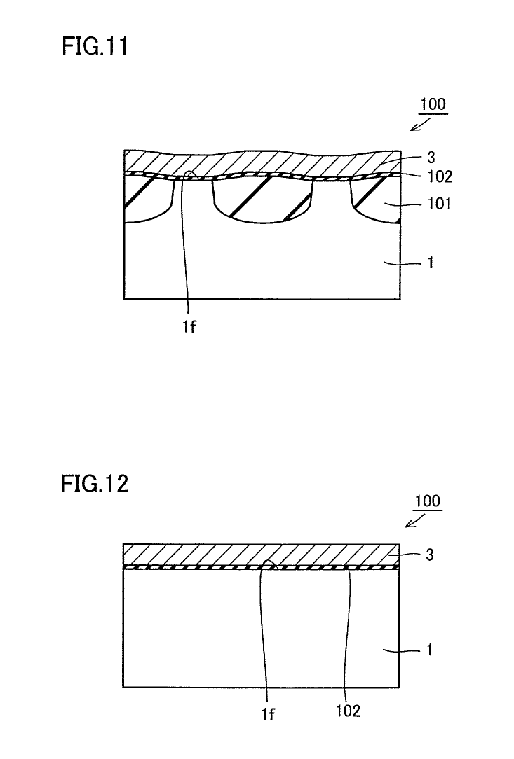

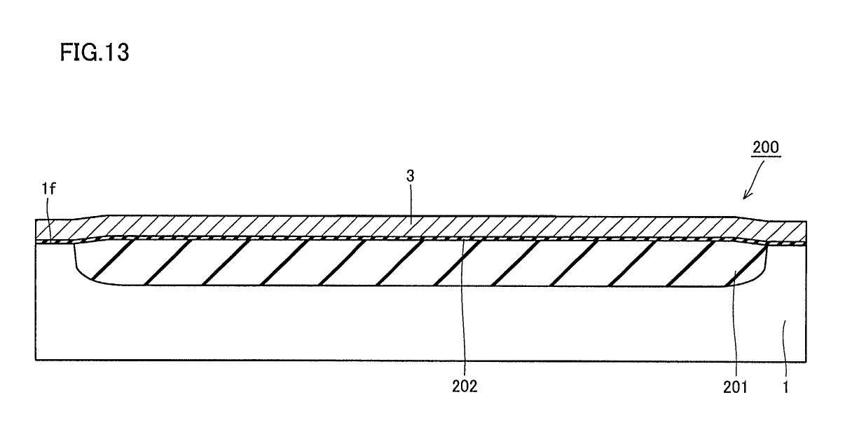

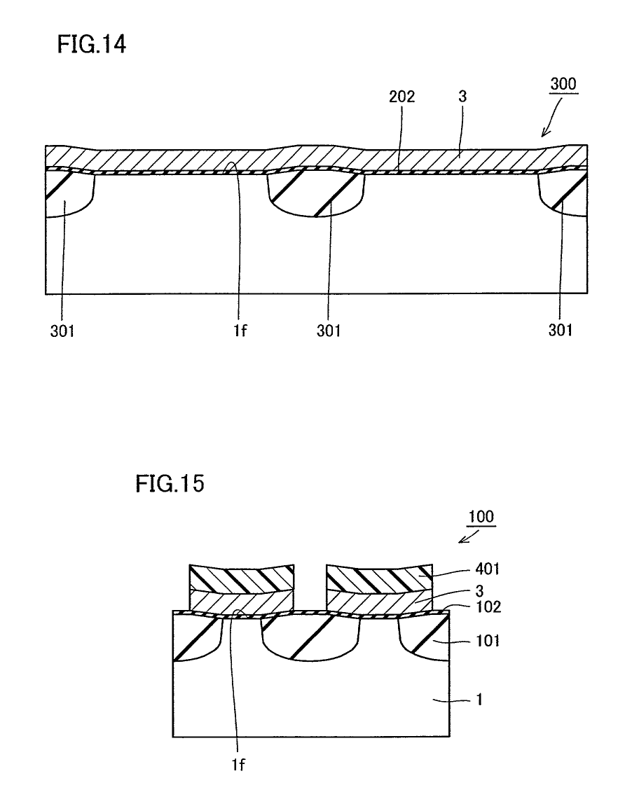

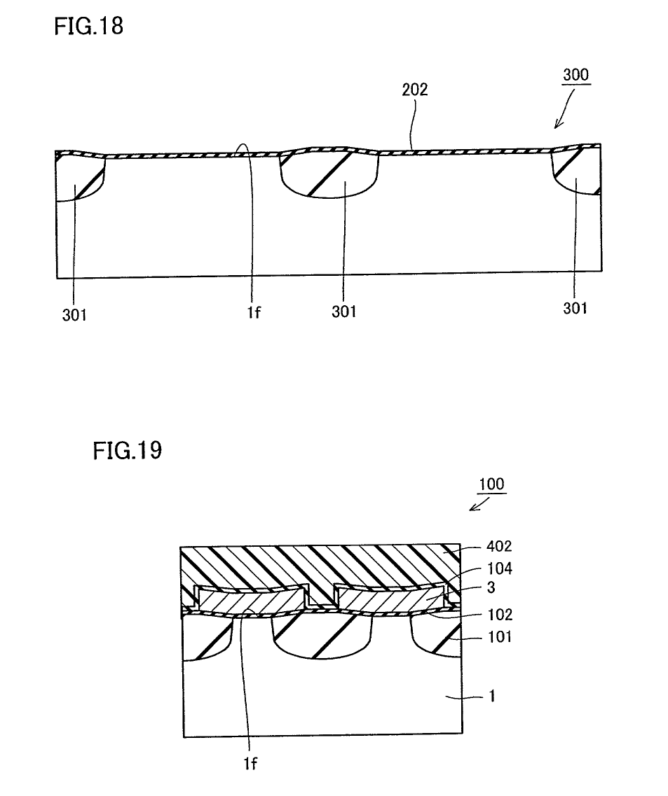

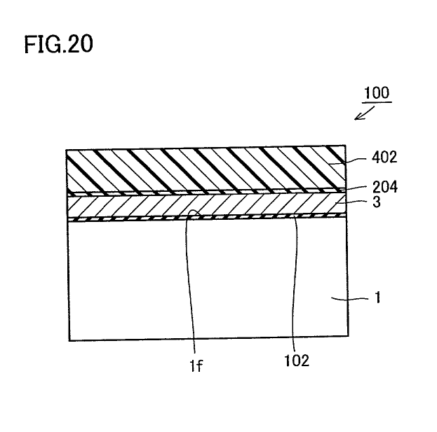

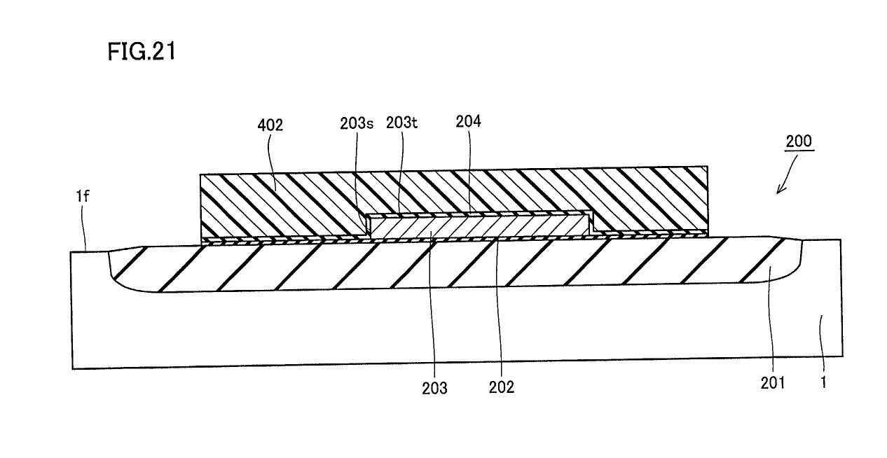

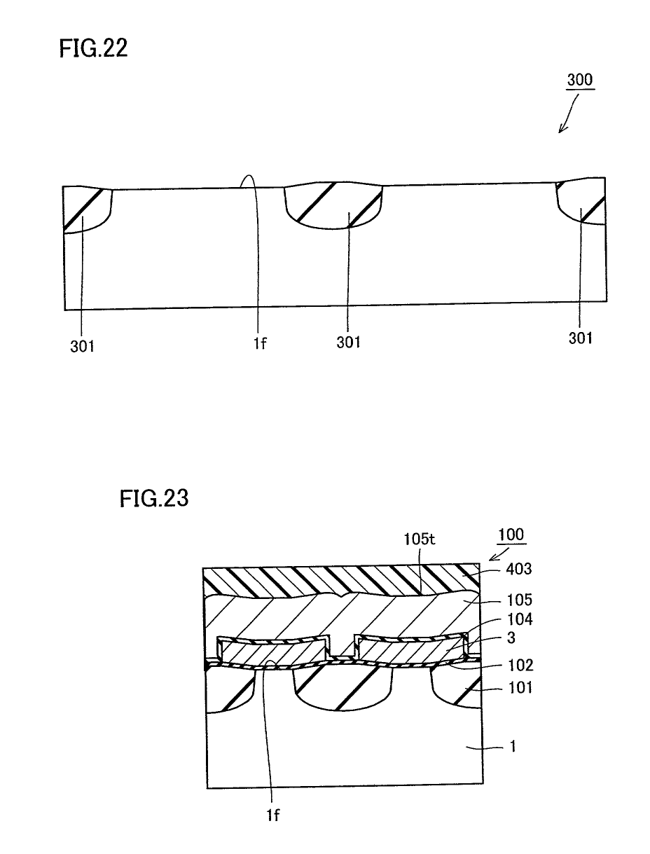

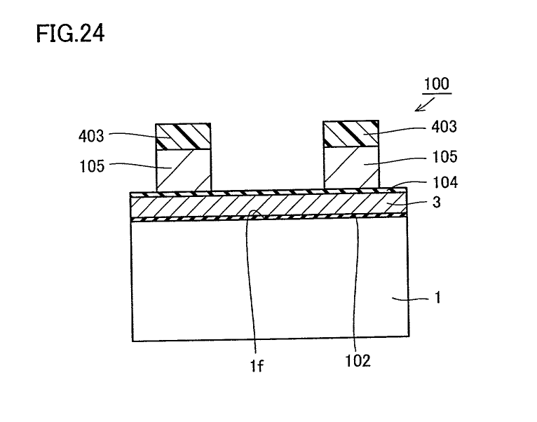

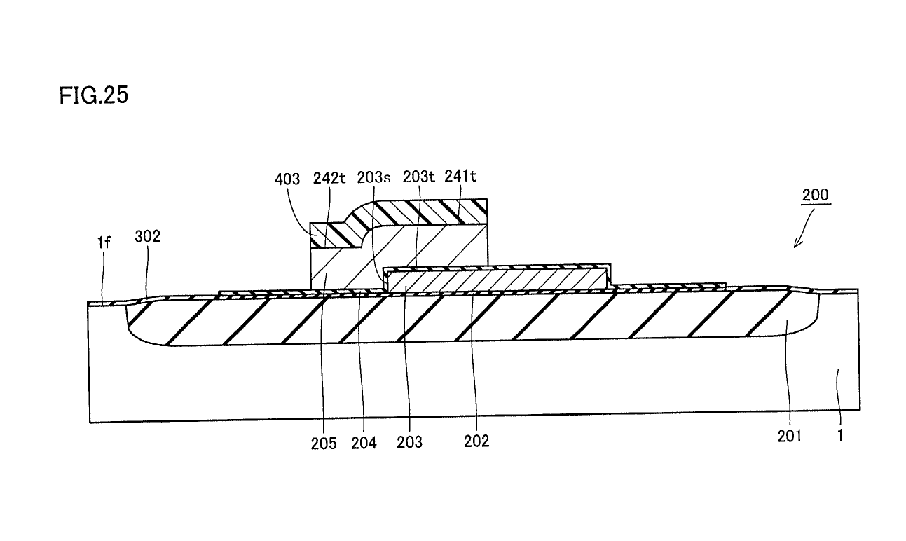

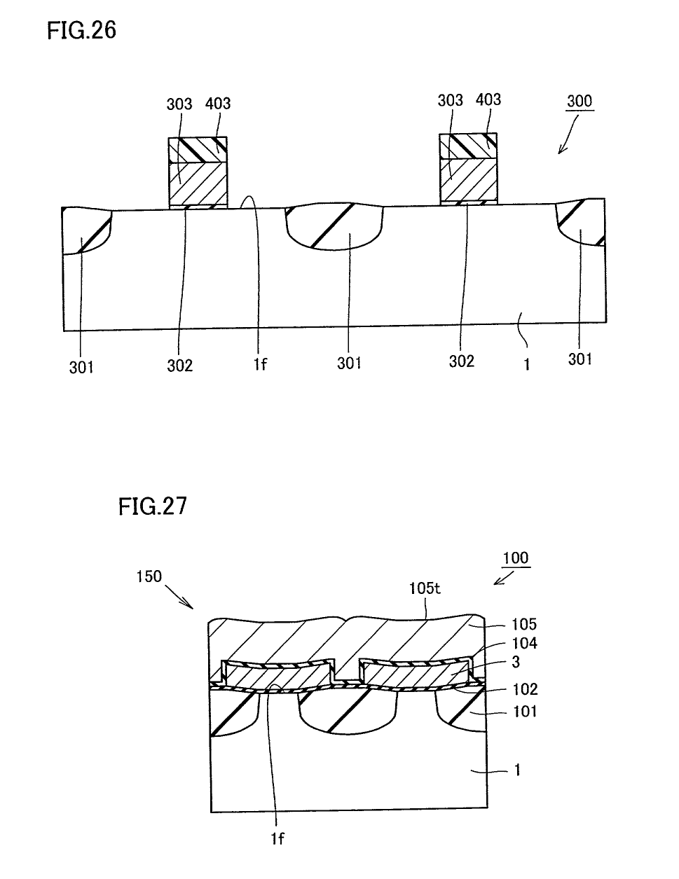

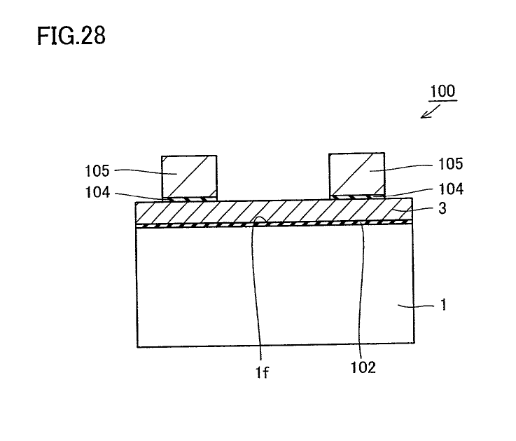

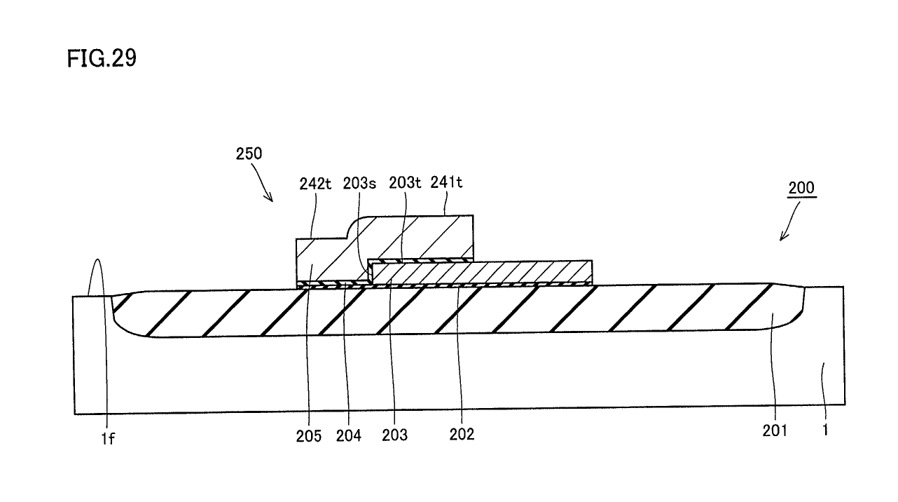

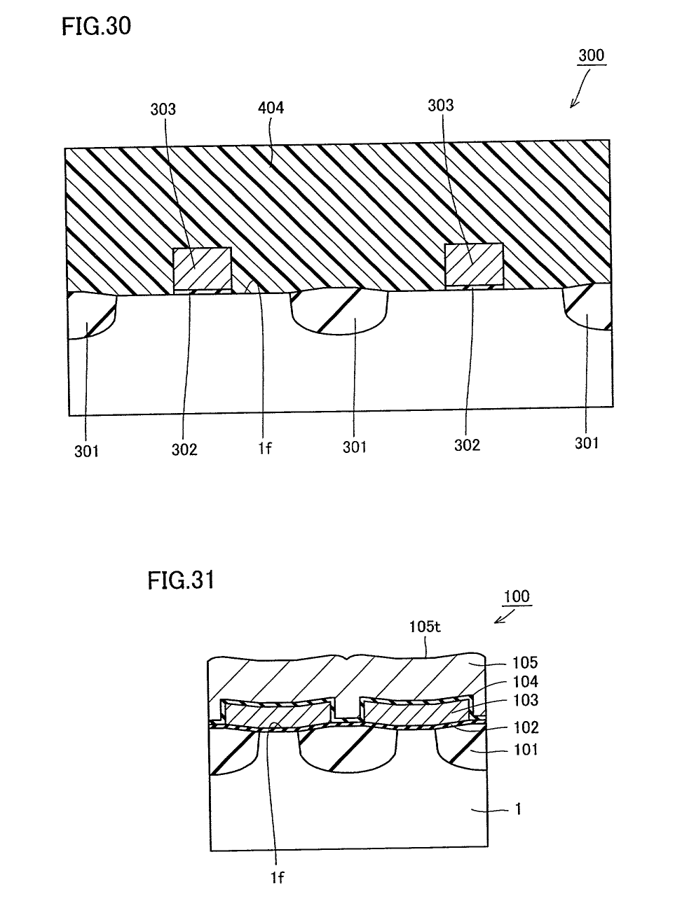

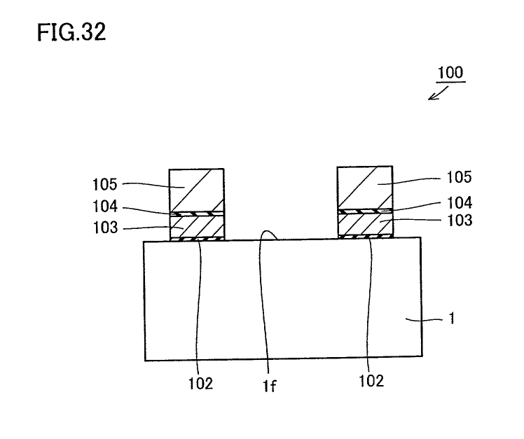

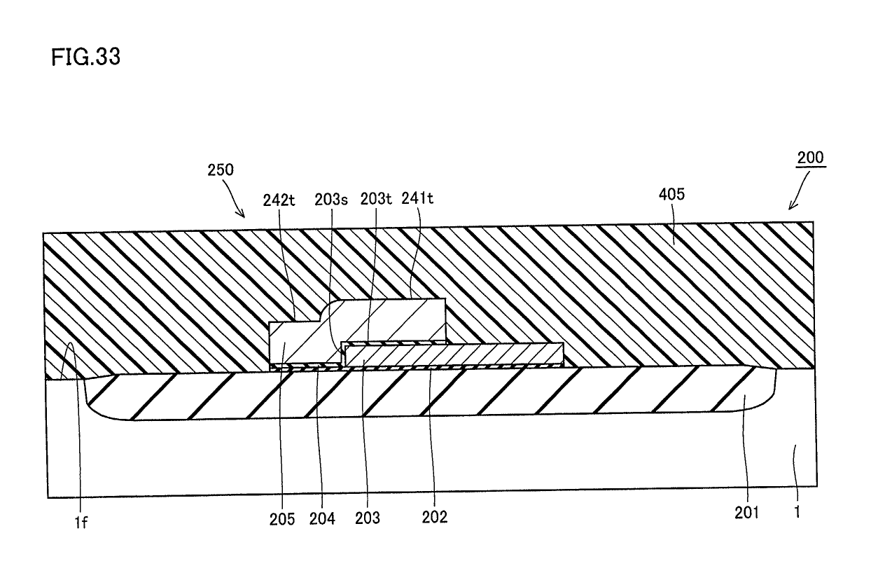

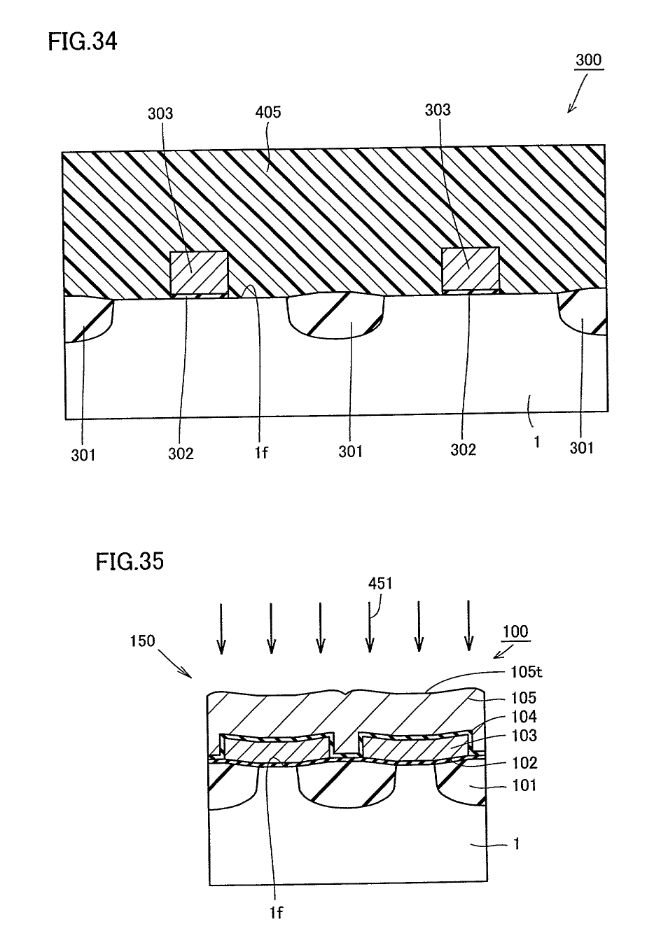

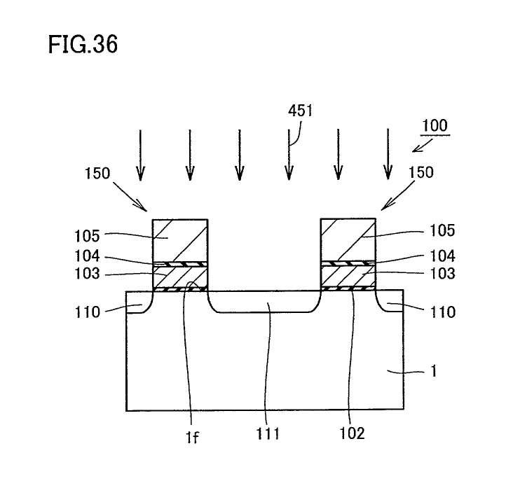

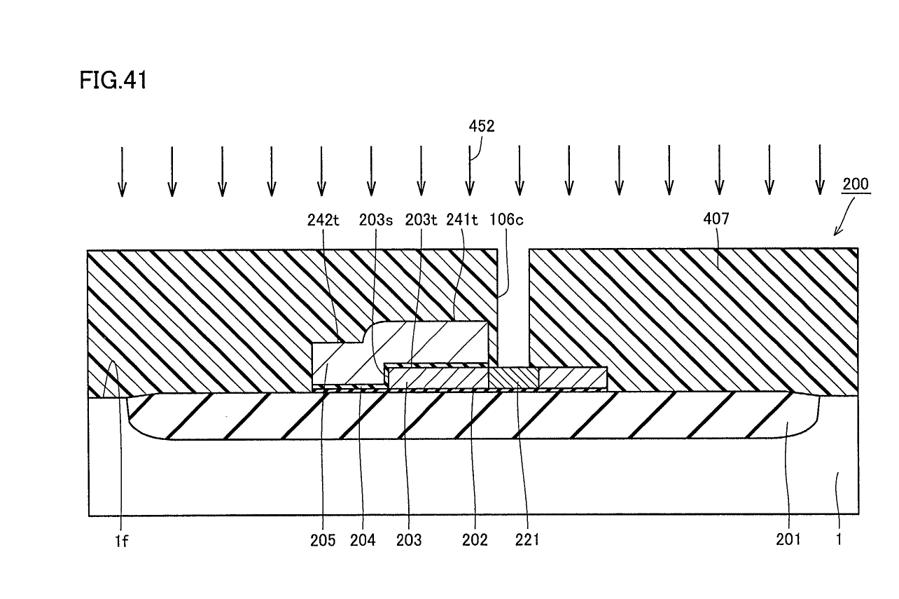

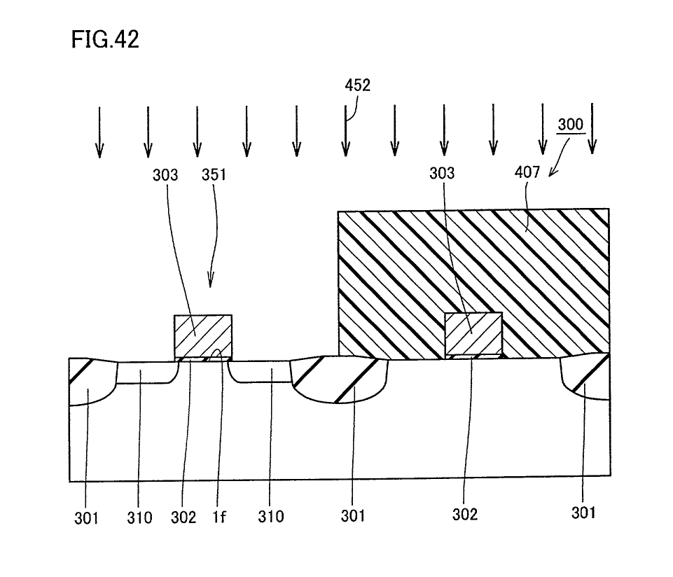

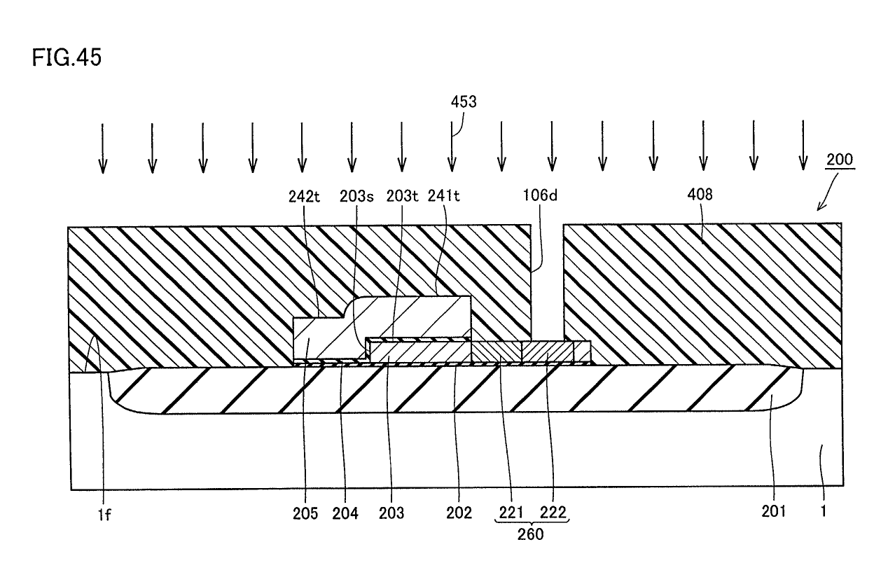

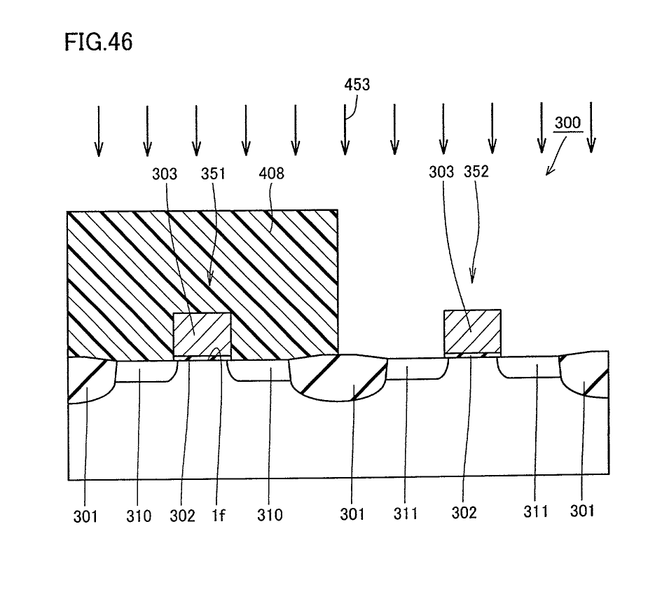

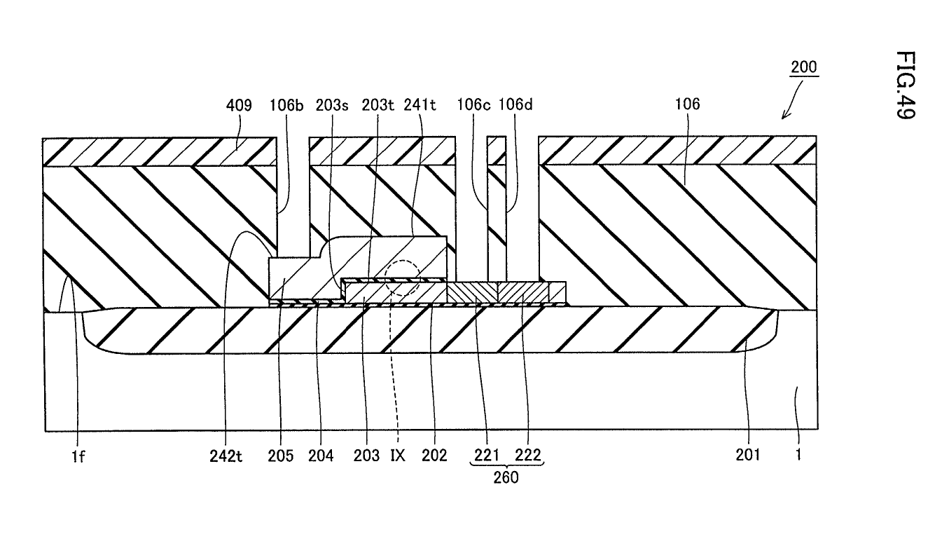

Next, a process for the nonvolatile semiconductor memory device shown in FIGS. 5 to 10 is described in the following. FIGS. 11, 15, 19, 23, 27, 31, 35, 39, 43 and 47 correspond to the cross section shown in FIG. 5. FIGS. 12, 16, 20, 24, 28, 32, 36, 40, 44 and 48 correspond to the cross section shown in FIG. 7. The cross sections shown in FIGS. 13, 17, 21, 25, 29, 33, 37, 41, 45 and 49 correspond to the cross section shown in FIG. 8. The cross sections shown in FIGS. 14, 18, 22, 26, 30, 34, 38, 42, 46 and 50 correspond to the cross section shown in FIG. 10.

Referring to FIGS. 11 to 14, field oxide films 101, 201 and 301 are formed on the surface of silicon substrate 1 as separation insulating films. As for the method of the formation of field oxide film 101, a local oxidation of silicon (LOCOS) method may be used. In addition, after forming a resist pattern on main surface 1f of silicon substrate 1, silicon substrate 1 is etched in accordance with this resist pattern so that a trench is created. And, then, field oxide films 101, 201 and 301 may be formed so as to fill in this trench.

Tunnel oxide films 102 and 202 are formed on silicon substrate 1. A polysilicon film 3 in which impurities are doped is deposited on tunnel oxide films 102 and 202. Here, polysilicon film 3 may be formed of an amorphous silicon film to which impurities are added.

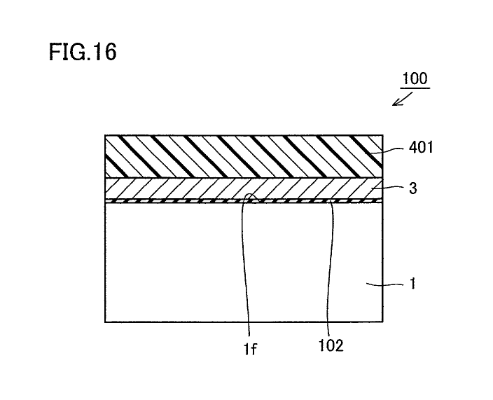

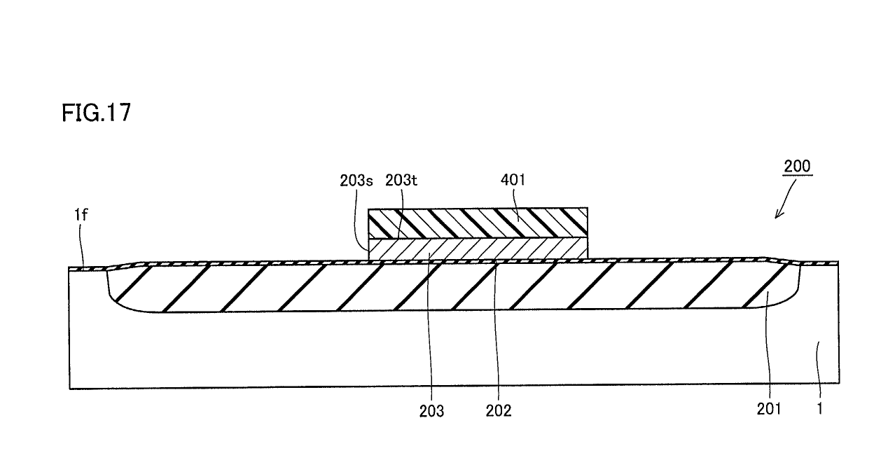

Referring to FIGS. 15 to 18, a resist is applied to polysilicon film 3. This resist is patterned through a photolithographic process and, thereby, a resist pattern 401 is formed. Resist pattern 401 covers portions of memory cell region 100 and periphery region 200. Polysilicon film 3 is etched by using resist pattern 401 as a mask. Thereby, polysilicon film 3 is patterned in memory cell region 100 shown in FIGS. 15 and 16. Polysilicon film 3 is patterned and, thereby, lower electrode 203 is formed in periphery region 200 shown in FIG. 17. Polysilicon film is completely removed from periphery circuit region 300 so that tunnel oxide film 202 is exposed.

Referring to FIGS. 19 to 22, a first silicon oxide film, a silicon nitride film and a second silicon oxide film are formed on silicon substrate 1. A resist is applied to the second silicon oxide film and the resist is patterned by means of a photolithographic process. Thereby, a resist pattern 402 is formed. The second silicon oxide film, the silicon nitride film and the first silicon oxide film are patterned by using resist pattern 402 as a mask and, thereby, first dielectric layer 104 and second dielectric layer 204 are formed. Here, the first silicon oxide film, the silicon nitride film and the second silicon oxide film are completely removed from periphery circuit region 300. First dielectric layer 104 and second dielectric layer 204 are so-called ONO films.

Referring to FIGS. 23 to 26, gate oxide film 302 is formed in periphery region 200 and in periphery circuit region 300. First and second dielectric layers 104 and 204 are formed and a polysilicon layer is formed so as to cover gate oxide film 302. A resist is applied to the polysilicon layer. This resist is patterned by means of a photolithographic process so that a resist pattern 403 is formed. The polysilicon film is patterned in accordance with the resist pattern 403 and, thereby, control gate electrode 105, upper electrode 205 and gate electrode 303 are formed.

Referring to FIGS. 27 to 30, a resist is applied to silicon substrate 1. This resist is patterned by means of a photolithographic process and, thereby, a resist pattern 404 is formed in periphery circuit region 300. First dielectric layer 104 and second dielectric layer 204 are etched in a self-aligning manner by using control gate electrode 105 and upper electrode 205 as a mask.

Referring to FIGS. 31 to 34, a resist is applied to silicon substrate 1 and this resist is patterned by means of a photolithographic process. Thereby, a resist pattern 405 is formed in periphery region 200 and in periphery circuit region 300. Polysilicon film 3 is etched in a self-aligning manner by using the control gate electrode as a mask in memory cell region 100. Thereby, floating gate electrode 103 is formed.

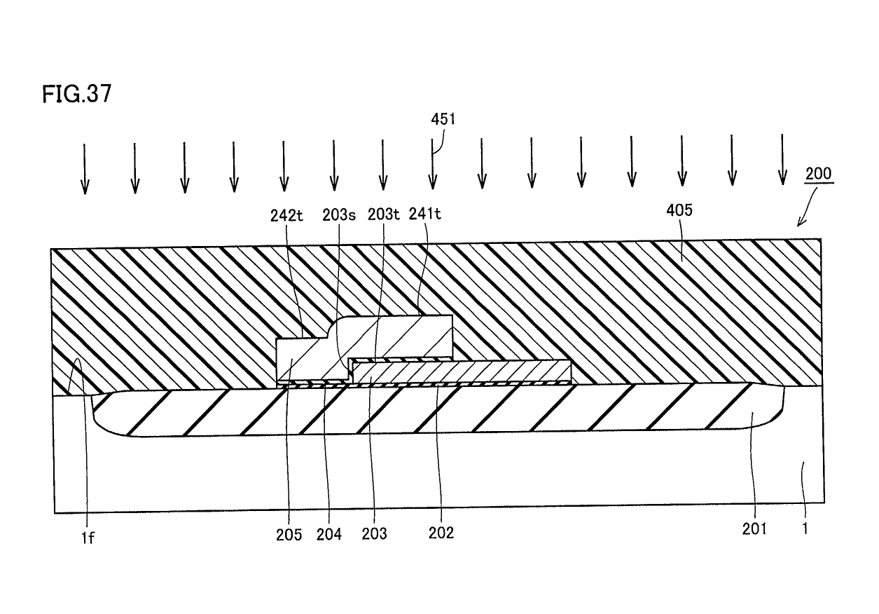

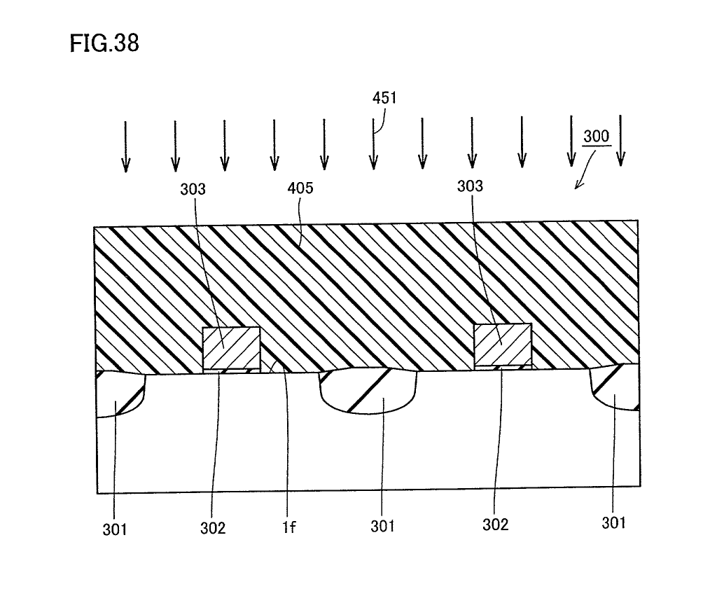

Referring to FIGS. 35 to 38, impurity ions are injected into silicon substrate 1 by using control gate electrode 105 as a mask in the direction shown by arrow 451 on main surface 1f of silicon substrate 1. Thereby, source region 110 and drain region 111 are formed on both sides of floating gate electrode 103. Here, source region 110 and drain region 111 are formed of impurity regions. Thereby, nonvolatile memory cell transistor 150 is formed of floating gate electrode 103, control gate electrode 105, source region 110 and drain region 111. Here, as shown in FIGS. 37 and 38, periphery region (ONO capacitor region) 200 and periphery circuit region 300 are covered with resist pattern 405 so as not to receive the injection of impurity ions.

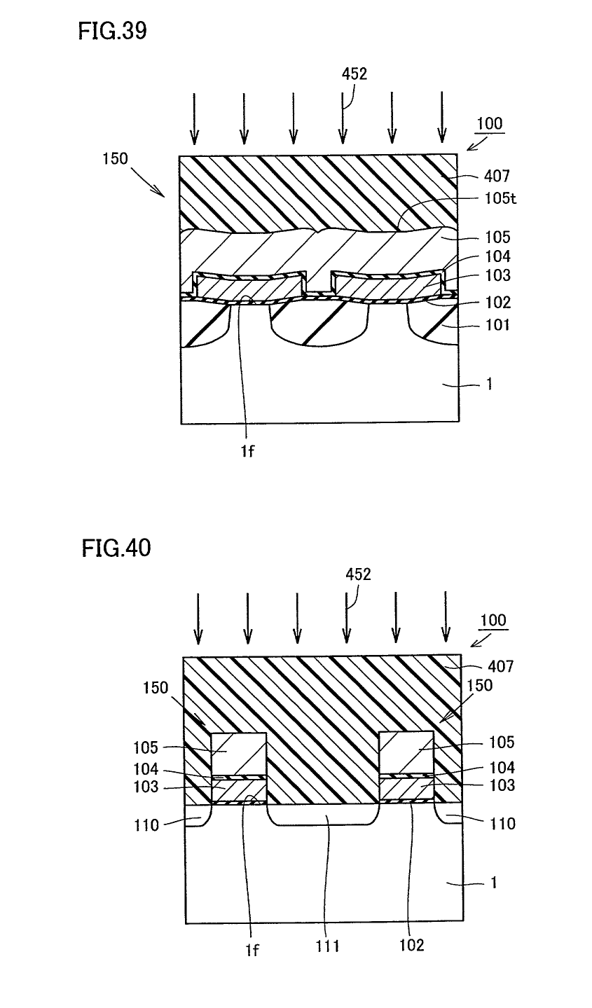

Referring to FIGS. 39 to 42, a resist is applied to silicon substrate 1 and this resist is patterned by means of a photolithographic process. Thereby, a resist pattern 407 is formed. N-type impurities, such as arsenic, are injected in the direction shown by arrow 452 by using resist pattern 407 and gate electrode 303 as a mask and, thereby, n-type region 221 and n-type impurity region 310 are formed. Thereby, as shown in FIG. 42, field effect transistor 351 is configured of gate electrode 303 formed above silicon substrate 1 by allowing gate oxide film 302 to intervene and of a pair of n-type impurity regions formed on both sides of gate electrode 303.

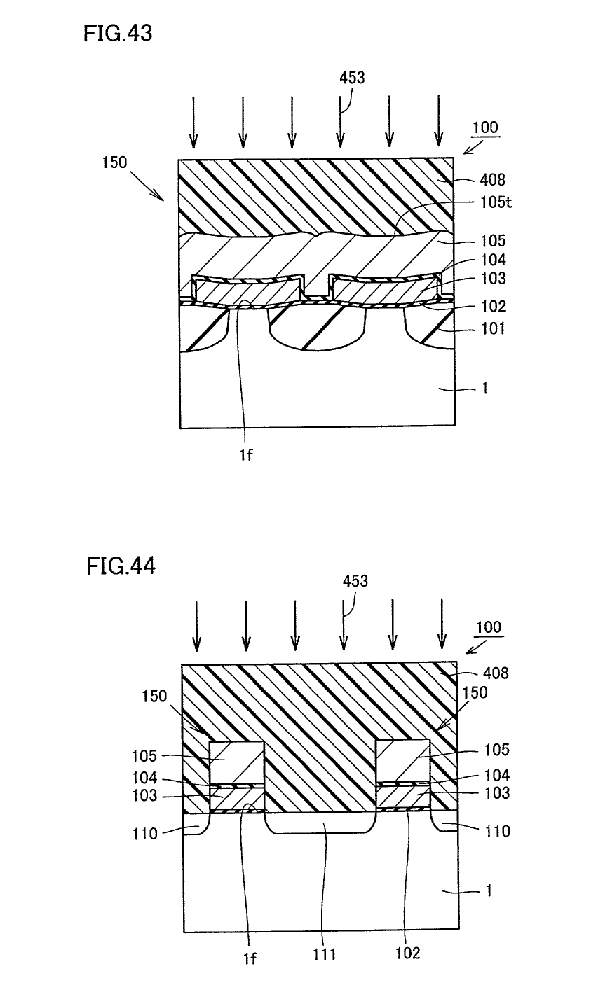

Referring to FIGS. 43 to 46, a resist is applied to silicon substrate 1 and this resist is patterned by means of a photolithographic process. Thereby, a resist pattern 408 is formed. P-type impurities, such as boron, are injected in the direction shown by arrow 453 by using resist pattern 408 and gate electrode 303 as a mask. Thereby, p-type region 222 and p-type impurity region 311 are formed. P-type field effect transistor 352 is, thus, completed and is configured of gate electrode 303 formed above main surface 1f of silicon substrate 1 by allowing gate oxide film 302 to intervene and of p-type impurity regions 311 formed in silicon substrate 1 in positions on both sides of gate electrode 303. In addition, diode 260 is also completed and has a structure wherein n-type region 221 and p-type region 222 are connected to each other.

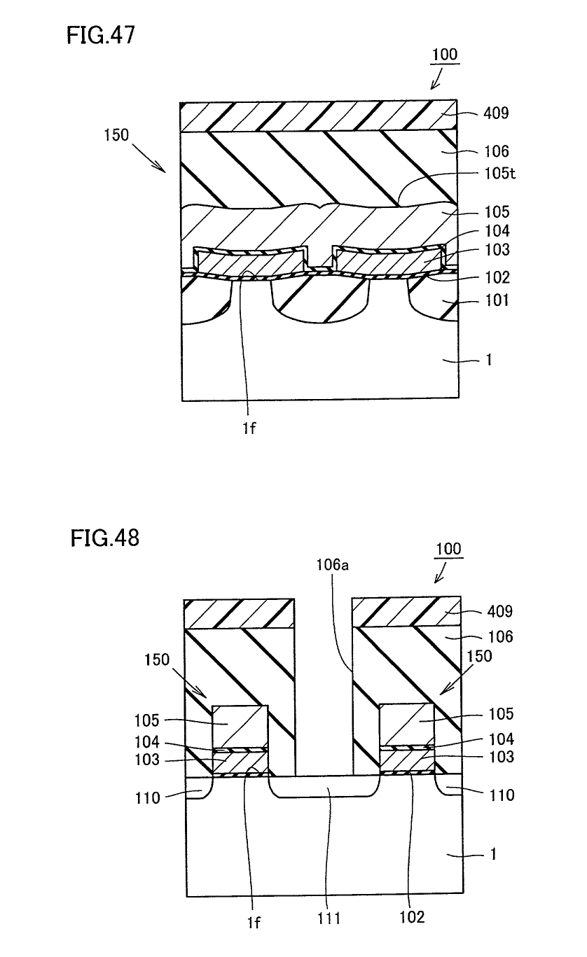

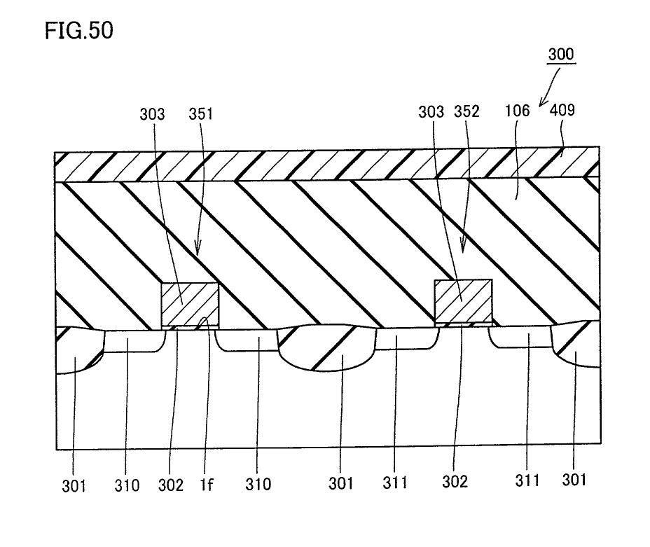

Referring to FIGS. 47 to 50, interlayer insulating film 106 made of silicon oxide film is deposited on silicon substrate 1. A resist is applied to interlayer insulating film 106 and this resist is patterned by means of a photolithographic process. Thereby, a resist pattern 409 is formed. Interlayer insulating film 106 is etched by using resist pattern 409 as a mask. Thereby, contact hole 106a, which reaches to drain region 111, contact hole 106b, which reaches to second top surface 242t of upper electrode 205, contact hole 106c, which reaches to n-type region 221 of diode 260, and contact hole 106d, which reaches to p-type region 222 of diode 260, are created. Here, as shown in FIG. 50, since the entire surface of periphery circuit region 300 is covered with resist pattern 409, no contact holes are created. However, contact holes may be created above source/drain regions 310 or 311 if necessary.

After that, an aluminum layer is formed on interlayer insulating film 106 so as to fill in contact holes 106a to 106d. A resist is applied to the aluminum layer and this resist is patterned by means of a photolithographic process so as to form a resist pattern. Wiring layers 107, 207 and 307 are formed through etching the aluminum layer by using the resist pattern as a mask. In such a manner, the semiconductor device shown in FIGS. 5 to 10 is completed.

In the nonvolatile semiconductor memory device according to the first embodiment of this invention which is formed in the above manner, as shown in FIG. 8, upper electrode 205 is configured of second top surface 242t, which is formed in the vicinity of field oxide film 201 and which is located in a relatively low position, and of first top surface 241t, which is overlaid onto lower electrode 203 and which is located in a relatively high portion. Since the height of second top surface 242t is lower than the height of first top surface 241t, second top surface 242 becomes closer to main surface 1f of silicon substrate 1 in comparison with first top surface 241t. Therefore, since the difference between the depth of contact hole 106b, which reaches to second top surface 242t, and the depth of contact hole 106a, which reaches to main surface 1f, becomes small, upper electrode 205 is not excessively etched through etching at the time of the creation of contact holes 106a and 106b. Therefore, wiring layer 207, which fills in contact hole 106b, does not contact lower electrode 203 so that the reliability of the nonvolatile semiconductor memory device can be improved.

In addition, upper electrode 205, second dielectric layer 104, tunnel oxide film 202 and field oxide film 201 are formed directly beneath contact hole 106b, while lower electrode 203 is not formed directly beneath contact hole 106b. Therefore, even in the case that upper electrode 205 and second dielectric layer 204 are excessively etched at the time of the creation of contact hole 106b through etching, contact hole 106b does not reach to lower electrode 203. As a result, the reliability of the nonvolatile semiconductor memory device can be improved.

In addition, floating gate electrode 103, lower electrode 203 and diode 260 are formed of the same polysilicon film. First dielectric layer 104 and second dielectric layer 204 are formed of the same dielectric layer. Control gate electrode 105, upper electrode 205 and gate electrode 303 are formed of the same polysilicon film. Thereby, the number of manufacturing steps can be reduced. In addition, since first and second dielectric layers 104 and 204 are so-called ONO films wherein first silicon oxide film 104a, silicon nitride film 104b and second silicon oxide film 104c are layered, the capacitance can be increased in comparison with the case where the above are formed of silicon oxide film only.

In addition, since capacitor 250 and diode 260 are formed on field oxide film 201, which is an insulator, capacitor 250 and diode 260 do not directly make direct contact with silicon substrate 1. As a result, capacitor 250 and diode 260, as elements, do not make short circuit with other elements and, thereby, the reliability of the nonvolatile semiconductor memory device is improved. Here, capacitor 250 and diode 260 are used as components of a charge up circuit which generates a high voltage for application to control gate electrode 105.

Furthermore, contact holes 106c and 106d, which reach to n-type region 221 and to p-type region 222 of diode 260, are created in interlayer insulating film 106. These contact holes 106c and 106d reach to the portions at the same level as top surface 203t of lower electrode 203 and, thereby, the difference between the depth of contact holes 106c and 106d and the depth of contact hole 106a becomes small. As a result, n-type region 221 and p-type region 222 are not excessively etched at the time when contact holes 106c and 106d are created and, thereby, the reliability of the nonvolatile semiconductor memory device is further improved.

(Second Embodiment)

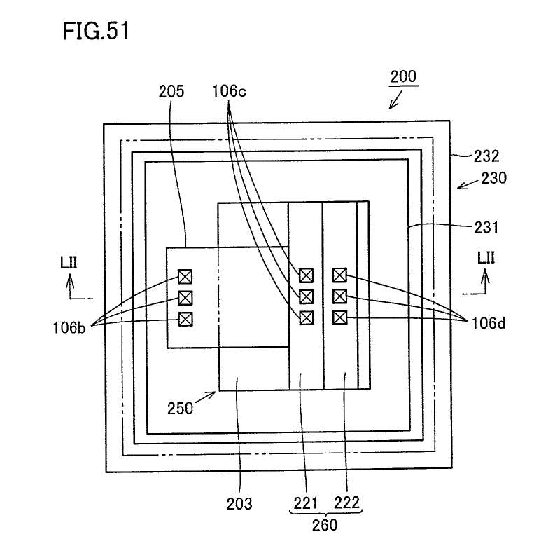

Referring to FIG. 51, in a nonvolatile semiconductor memory device according to a second embodiment of this invention, periphery region 200 is different from periphery region 200 according to the first embodiment in the point that an external periphery layer 230 which surrounds capacitor 250 is formed. External periphery layer 230 is formed in a ring form and includes a lower electrode 231 and an upper electrode 232.

Though external periphery layer 230 is formed in an approximately rectangular form so as to surround capacitor 250, the form of external periphery layer 230 is not limited to this and it is possible to make it in a variety of forms such as in a circular form, in a triangular form or in a pentagonal form.

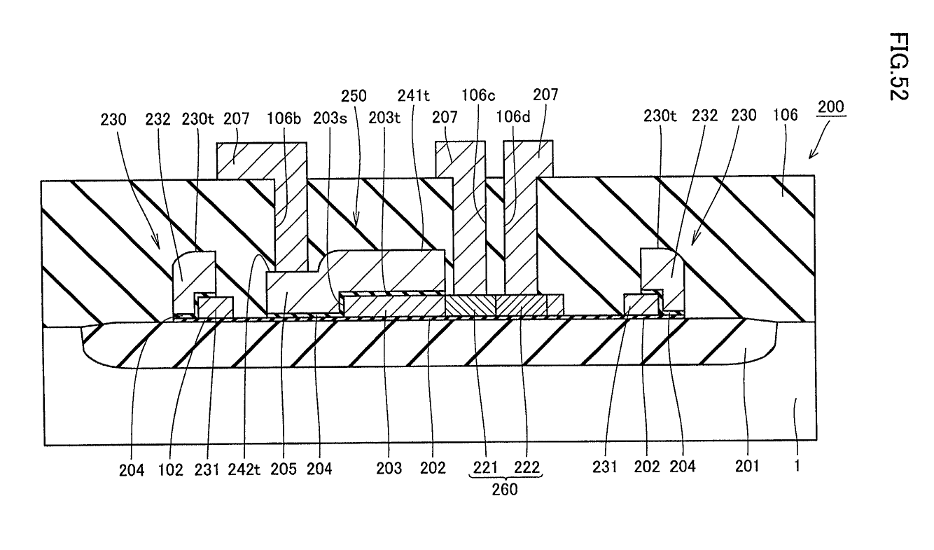

Referring to FIG. 52, in a nonvolatile semiconductor memory device according to the second embodiment of this invention, periphery region 200 is different from the periphery region 200 according to the first embodiment in the point that external periphery layer 230 is formed in periphery region 200. External periphery layer 230 is formed on field oxide film 201. External periphery layer 230 has lower electrode 231, second dielectric layer 204 formed on lower electrode 231 and upper electrode 232 formed on second dielectric layer 204. Upper electrode 232 has top surface 230t of external periphery layer 230. The height of top surface 230t is approximately equal to the height of first top surface 241t. Lower electrode 231 and lower electrode 203 are formed of the same layer. Upper electrode 232 and upper electrode 205 are formed of the same layer.

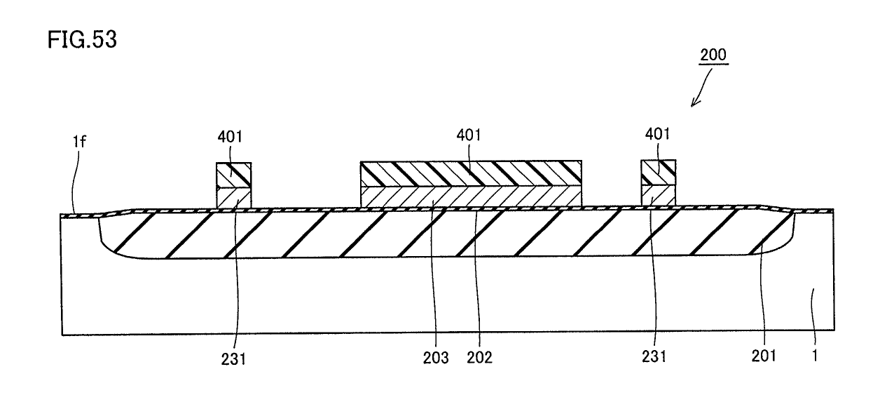

Next, a process for the nonvolatile semiconductor memory device which has periphery region 200 shown in FIGS. 51 and 52 is described. Referring to FIG. 53, field oxide film 201 and tunnel oxide film 202 are formed on silicon substrate 1 in accordance with the same steps as in the first embodiment and a polysilicon film is formed on tunnel oxide film 202. A resist is applied to the polysilicon film and a resist pattern 401 is formed by patterning this resist in a predetermined form. Lower electrode 203 of the capacitor and lower electrode 231 of the external periphery layer are formed through etching of the polysilicon film by using resist pattern 401 as a mask.

After that, second dielectric layer 204 is formed in accordance with the same steps as in the first embodiment and a polysilicon film is formed on second dielectric layer 204. A resist is applied to the polysilicon film and a resist pattern 403 is formed by patterning this resist by means of a photolithographic process. Upper electrodes 205 and 232 are formed through etching of the polysilicon film by using resist pattern 403 as a mask. Thereby, capacitor 250 and external periphery layer 230 are formed. After that, the nonvolatile semiconductor memory device shown in FIGS. 51 and 52 is completed in accordance with the same steps as the steps in the first embodiment.

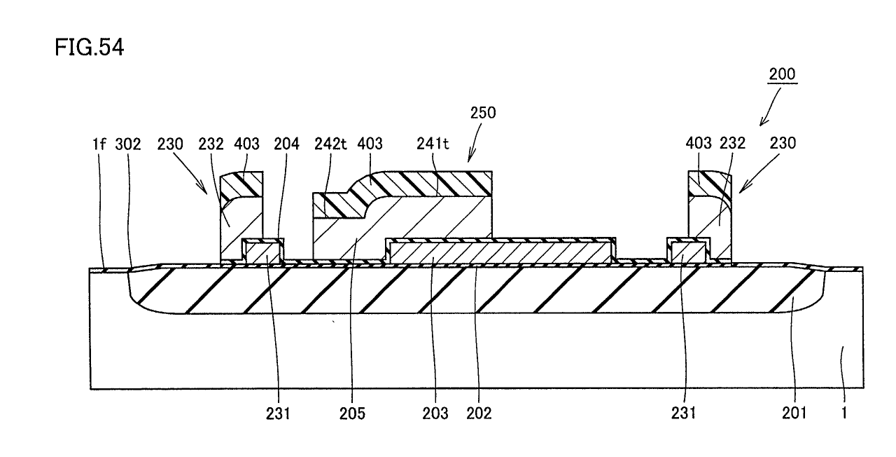

In the non-volatile semiconductor device formed in such a manner, first, the same effects can be gained as of the nonvolatile semiconductor memory device according to the first embodiment. Moreover, external periphery layer 230 is formed so as to cover capacitor 250. Since the height of top surface 230t of external periphery layer 230 is approximately equal to the height of first top surface 241t of upper electrode 205 of capacitor 250, a resist will not flow into the surrounding area from top electrode 205 even in the case that this resist is applied in the step shown in FIG. 54. Moreover, even in the case that an interlayer insulating film is formed on the upper electrode in the subsequent steps, the silicon oxide film which forms the interlayer insulating film will not flow into the surrounding area of capacitor 250. That is to say, since the heights of capacitor 250 and external periphery layer 230 can be made approximately equal, flatness of the elements on field oxide film 201 can be increased. As a result, it becomes unnecessary to carry out flattening processing in subsequent steps. Thereby, the reliability of the nonvolatile semiconductor memory device is improved.

Furthermore, since capacitor 250 is surrounded by external periphery layer 230 at the time when second dielectric layer 204 is removed through wet etching in the subsequent steps, the etching liquid does not excessively contact capacitor 250. As a result, second dielectric layer 204, which forms capacitor 250, is not excessively etched so that the capacitance of the capacitor can be prevented from being lowered.

(Third Embodiment)

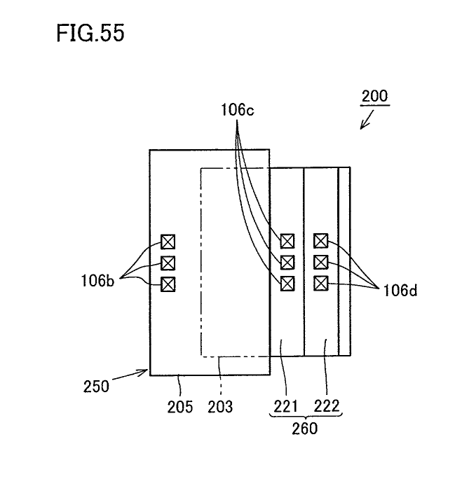

Referring to FIG. 55, in periphery region 200 of a nonvolatile semiconductor memory device according to a third embodiment of this invention, upper electrode 205 is larger than upper electrode 205 of the first and second embodiments and capacitor 250 is different from capacitor 250 according to the first embodiment in the point that upper electrode 205 covers a major portion of lower electrode 203. Upper electrode 205 is formed in a plate form and the plane area thereof is larger than that of upper electrode 205 of the first embodiment.

In the nonvolatile semiconductor memory device according to the third embodiment of this invention which is formed in such a manner, first, the same effects are gained as in the nonvolatile semiconductor memory device according to the first embodiment. Furthermore, since the area of upper electrode 205 becomes larger in periphery region 200, the area where upper electrode 205 and lower electrode 203 face each other becomes larger. As a result, the capacitance of capacitor 250 can be further increased.

(Fourth Embodiment)

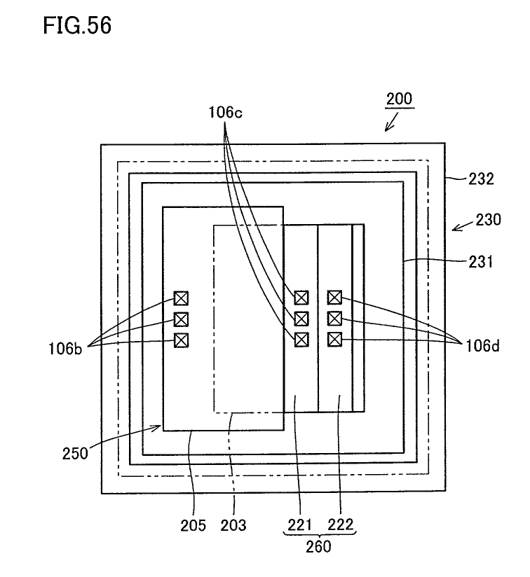

Referring to FIG. 56, periphery region 200 of a nonvolatile semiconductor memory device according to a fourth embodiment of this invention is different from periphery region 200 according to the third embodiment in the point that external periphery layer 230 is provided so as to cover capacitor 250. External periphery layer 230 is formed in the same manner as external periphery layer 230 shown in the second embodiment.

In the nonvolatile semiconductor memory device formed in such a manner, all of the effects shown in the first to third embodiments are gained.

(Fifth Embodiment)

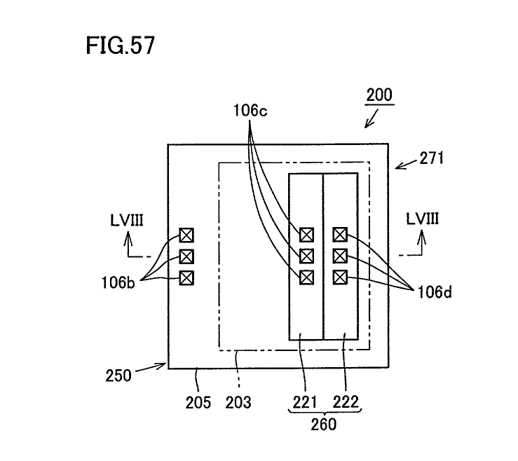

Referring to FIG. 57, periphery region 200 of a nonvolatile semiconductor memory device according to a fifth embodiment of this invention is different from periphery region 200 shown in the first embodiment in the point that a girdling gate 271 is provided in upper electrode 205 and the entirety of the periphery portion of lower electrode 203 is covered with upper electrode 205. Upper electrode 205 covers almost entirety of lower electrode 203 and diode 260 is formed in a portion which is not covered by upper electrode 205.

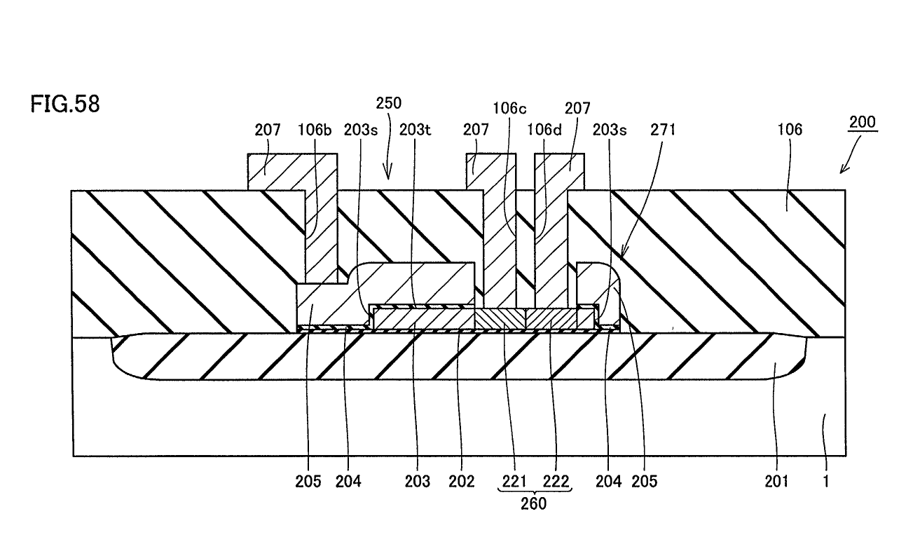

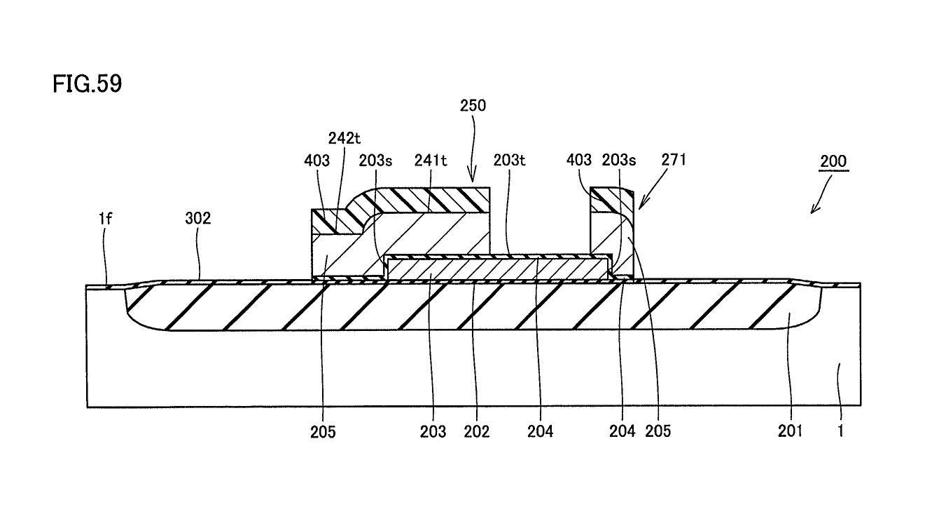

Referring to FIG. 58, periphery region 200 is different from periphery region 200 according to the first embodiment in the point that girdling gate 271 formed of upper electrode 205 is provided. Thereby, upper electrode 205 faces the entire surface of the side surface 203s of lower electrode 203 by allowing second dielectric layer 204 to intervene. Diode 260 is formed in a region which is not covered by upper electrode 205.

In the nonvolatile semiconductor memory device according to the fifth embodiment of this invention which is formed in such a manner, first, the same effects as in the nonvolatile semiconductor memory device according to the first embodiment are gained. Moreover, since the entirety of side surface 203s of lower electrode 203 is covered with upper electrode 205, the area where lower electrode 203 and upper electrode 205 face each other can be made larger so that the capacitance of capacitor 250 can be further increased.

First, field oxide film 201, tunnel oxide film 202, lower electrode 203 and second dielectric layer 204 are formed on silicon substrate 1 in the same manner as in the first embodiment. A polysilicon film is formed on second dielectric layer 204. A resist is applied to the polysilicon film and the resist is patterned by means of a photolithographic process. Thereby, a resist pattern 403 is formed. Upper electrode 205 is formed by etching the polysilicon film in accordance with resist pattern 403. Upper electrode 205 covers the entirety of side surface 203s of lower electrode 203. Upper electrode 205 has girdling gate 271. After that, the nonvolatile semiconductor memory device, which has the periphery region shown in FIGS. 57 and 58, is completed in accordance with the same steps as the steps of the first embodiment.

(Sixth Embodiment)

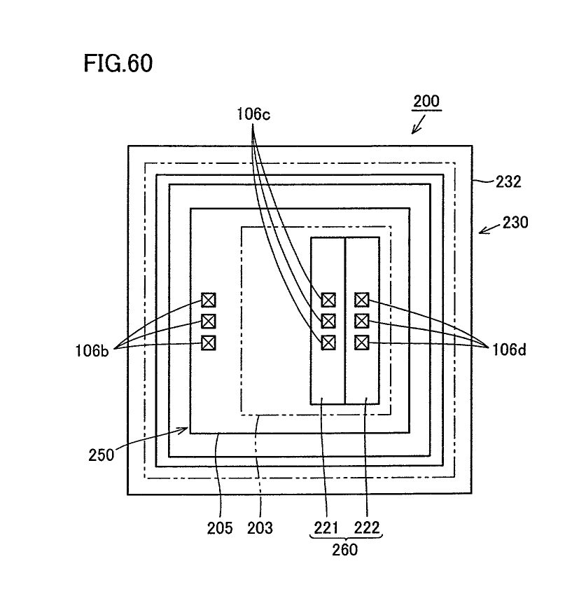

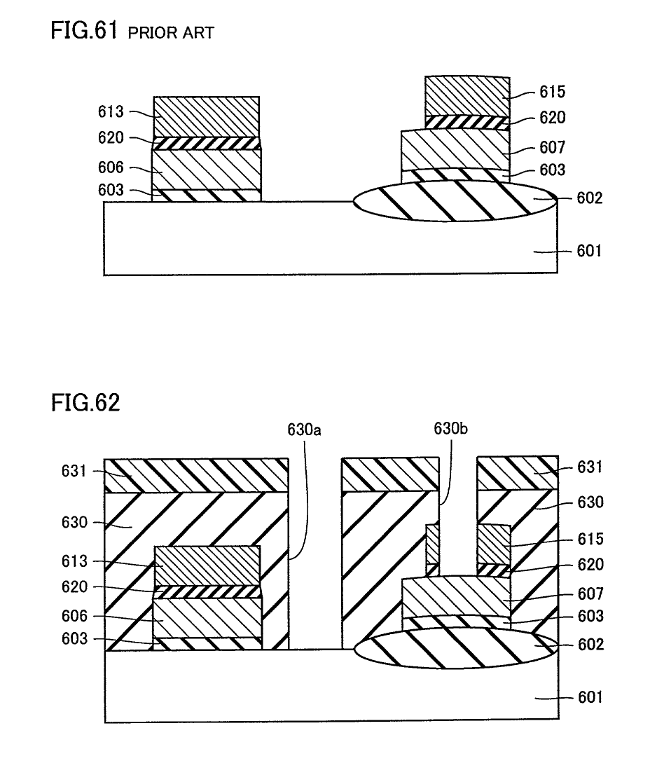

Referring to FIG. 60, periphery region 200 of a nonvolatile semiconductor memory device according to a sixth embodiment of this invention is different from periphery region 200 of the nonvolatile semiconductor memory device according to the fifth embodiment in the point that external periphery layer 230, which surrounds capacitor 250, is formed.

In the nonvolatile semiconductor memory device according to the sixth embodiment which is formed in such a manner, the effects of the nonvolatile semiconductor memory device according to the fifth embodiment and of the nonvolatile semiconductor memory device according to the second embodiment are gained.

Though the embodiments of this invention are described in the above manner, it is possible to modify the embodiments shown herein in a variety of other manners. First, as for the conductive layer, for example, not only the above described polysilicon is used but, also, a metal layer, such as of titanium silicide or of tungsten silicide, may be provided on a polysilicon layer. Furthermore, as for the wiring layer, not only an aluminum alloy but, also, tungsten, or the like, may be used. In addition, a plurality of capacitors and diodes are formed in the periphery region and a charge up circuit may be formed by connecting these.

According to this invention, a nonvolatile semiconductor memory device of a high reliability can be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A nonvolatile semiconductor memory device comprising:
a semiconductor substrate;
a nonvolatile memory cell transistor formed on said semiconductor substrate; and
a capacitor formed on said semiconductor substrate,
wherein said nonvolatile memory cell transistor includes:
a floating gate electrode formed on said semiconductor substrate with a gate insulating film interposed therebetween;
a first dielectric layer formed on said floating gate electrode; and
a control gate electrode formed on said first dielectric layer,
wherein said capacitor includes:
a lower electrode formed on said semiconductor substrate;
a second dielectric layer formed on said lower electrode; and
an upper electrode having a portion formed on said lower electrode with said second dielectric layer interposed therebetween,
wherein said floating gate electrode and said lower electrode include conductive layers arranged in the same layer,
wherein said first dielectric layer and said second dielectric layer include dielectric layers arranged in the same layer,
wherein said control gate electrode and said upper electrode include conductive layers arranged in the same layer,
and wherein said upper electrode has a first top surface that is positioned in a portion relatively far away from said semiconductor substrate and a second top surface that is formed on said semiconductor substrate so as to continue to said first said top surface and that is positioned in a portion relatively close to said semiconductor substrate.

2. The nonvolatile semiconductor memory device according to claim 1, wherein said first dielectric layer and said second dielectric layer have a structure wherein a first silicon oxide film, a silicon nitride film and a second silicon oxide film are sequentially layered.

3. The nonvolatile semiconductor memory device according to claim 1, further comprising an interlayer insulating film formed on said semiconductor substrate, wherein a first hole which reaches to said semiconductor substrate and a second hole which reaches to said second top surface of said upper electrode are formed in said interlayer insulating film.

4. The nonvolatile semiconductor memory device according to claim 1, wherein said semiconductor substrate has a main surface and said main surface, said first top surface and said second top surface are substantially parallel to each other.

5. The nonvolatile semiconductor memory device according to claim 1, further comprising a separation insulating film formed on said semiconductor substrate, wherein said lower electrode and said upper electrode are formed on said separation insulating film.

6. The nonvolatile semiconductor memory device according to claim 1, further comprising a diode connected to said lower electrode.

7. The nonvolatile semiconductor memory device according to claim 6, wherein said diode and said lower electrode are formed of the same layer so as to directly contact each other.

8. The nonvolatile semiconductor memory device according to claim 7, further comprising an interlayer insulating film formed on said semiconductor substrate, wherein a first hole which reaches to said semiconductor substrate, a second hole which reaches to said second top surface of said upper electrode and a third hole which reaches to said diode are formed in said interlayer insulating film.

9. The nonvolatile semiconductor memory device according to claim 1, wherein said lower electrode has a top surface and a side surface and wherein said upper electrode faces a portion of said top surface and a portion of said side surface of said lower electrode with said second dielectric layer interposed therebetween.

10. The nonvolatile semiconductor memory device according to claim 9, wherein said upper electrode faces the entirety of said side surface with said second dielectric layer interposed therebetween.

11. The nonvolatile semiconductor memory device according to claim 1, further comprising an external periphery layer formed on said semiconductor substrate so as to surround said upper electrode and said lower electrode, wherein the height of the top surface of said external periphery layer and the height of the first top surface of said upper electrode are substantially equal.

12. The nonvolatile semiconductor memory device according to claim 11, wherein said external periphery layer is formed of the same layers as the layers forming said lower electrode, said second dielectric layer and said upper electrode.

13. The nonvolatile semiconductor memory device according to claim 1, further comprising a memory cell region wherein said nonvolatile memory cell transistor is formed and a periphery region wherein said capacitor is formed.
